(19) United States
(12) Patent Application Publication
(10) Pub. No.: US 2026/0123317 A1
(43) Pub. Date: Apr. 30, 2026

(54) METHOD OF PROCESSING WAFER AND METHOD OF MANUFACTURING PROCESSED WAFER

(71) Applicant: DISCO CORPORATION, Tokyo (JP)

(72) Inventors: Koichi MAKINO, Tokyo (JP); Atsushi KOMATSU, Tokyo (JP); Hironobu OZAWA, Tokyo (JP)

(21) Appl. No.: 19/353,246

(22) Filed: Oct. 8, 2025

(30) Foreign Application Priority Data
Oct. 28, 2024 (JP) 2024-189153

(51) Int. Cl. H01L 21/304; B24B 9/06

(52) U.S. Cl. CPC H10P 52/00; B24B 9/065

(57) ABSTRACT

A method of processing a wafer by processing a first wafer having a beveled part on an outer circumferential edge thereof includes holding, on a first holding surface of a first chuck table, a second surface side of the first wafer that is opposite a first surface side thereof such that the first surface side of the first wafer is exposed and after the second surface side of the first wafer has been held, processing the outer circumferential edge of the first wafer to remove the beveled part on the outer circumferential edge of the first wafer in its entirety or a portion of the beveled part on the first surface side. The first wafer is progressively smaller in diameter from the first surface side toward the second surface side in a region of the outer circumferential edge of the first wafer that has been processed.

### BACKGROUND OF THE INVENTION

### FIELD OF THE INVENTION

The present invention relates to a method of processing a wafer by processing a first wafer having a beveled part on an outer circumferential edge thereof for use in a laminated wafer and a method of manufacturing a processed wafer by manufacturing a processed first wafer having a beveled part on an outer circumferential edge thereof for use in a laminated wafer.

### DESCRIPTION OF THE RELATED ART

Device chips that contain integrated circuits (ICs), for example, are indispensable components for various electronic appliances including cellular phones and personal computers. Device chips are manufactured by grinding and polishing a wafer that has a plurality of devices in a first surface thereof from a second surface thereof opposite the first surface until the wafer is thinned down to a desired thickness and then dividing the wafer along boundary lines between the devices.

When device chips are manufactured from a wafer, the wafer tends to be chipped or cracked at its outer circumferential edge. To prevent the wafer from being damaged, the outer circumferential edges of wafers are often beveled. However, if a wafer having a beveled outer circumferential edge is ground from its second surface, a portion near its first surface of the beveled outer circumferential edge is left unremoved and shaped like a knife edge. The outer circumferential edge that is shaped like a knife edge is liable to crack due to stresses that are likely to concentrate thereon. It has been the conventional practice to perform edge trimming on the wafer before the wafer is ground from the second surface, thereby cutting off a portion near the first surface of the beveled outer circumferential edge in the process of fabricating device chips from the wafer (see, for example, JP 2000-173961A).

### SUMMARY OF THE INVENTION

The edge trimming process produces a wall surface extending near the outer circumferential edge steeply perpendicularly to the first surface of the wafer and a terrace extending from the base of the wall surface toward the outer circumferential edge. The wall surface and the like suffer minute damage including cracks and chips caused by the edge trimming process. The damaged part may collapse into debris in subsequent processes on the wafer. The debris is undesirable because it may scatter around onto the surfaces of the wafer, tending to be detrimental to the quality of the device chips that will eventually be fabricated from the wafer by dividing the wafer. According to one solution, the wafer that has been edge-trimmed is processed to remove the damaged area from the wall surface. The processes performed on the wafer to remove the damaged area include an etching process using an etching solution, i.e., a wet etching process, and a polishing process using a soft polishing pad, e.g., a chemical mechanical polishing (CMP) process.

When the wet etching process is performed on the wafer, the etching solution may be left on joints between the wall surface and the terrace, possibly causing yet other damage to the wafer. In recent years, laminated wafers have been fabricated by bonding two or more wafers to produce high-performance device chips from the laminated wafers. After wet etching is performed on the laminated wafer, if the etching solution is not smoothly drained from the laminated wafer, it acts on and damages the joined surfaces of the laminated wafer. In addition, when the laminated wafer is polished by the CMP process, the polishing pad may fail to sufficiently polish the wall surface of the laminated wafer as the polishing pad is not likely to be brought into full contact the wall surface that lies perpendicularly to the surfaces of the laminated wafer.

It is therefore an object of the present invention to provide a method of processing a wafer in a manner to prevent debris from occurring from an edge-trimmed outer circumferential edge of the wafer and a method of manufacturing a processed wafer in a manner to prevent debris from being produced from an edge-trimmed outer circumferential edge of the wafer.

In accordance with an aspect of the present invention, there is provided a method of processing a wafer by processing a first wafer having a beveled part on an outer circumferential edge thereof, including holding, on a first holding surface of a first chuck table, a second surface side of the first wafer that is opposite a first surface side thereof such that the first surface side of the first wafer is exposed and after the second surface side of the first wafer has been held, processing the outer circumferential edge of the first wafer to remove the beveled part on the outer circumferential edge of the first wafer in its entirety or a portion of the beveled part on the first surface side, in which the first wafer is progressively smaller in diameter from the first surface side toward the second surface side in a region of the outer circumferential edge of the first wafer that has been processed.

Preferably, in the method according to the aspect of the present invention the first chuck table is rotatable about a rotational axis extending through a center of the first holding surface across the first holding surface, and the outer circumferential edge of the first wafer is processed by either preparing a cutting blade mounted on a spindle and rotating the spindle to rotate the cutting blade while causing the cutting blade to cut into the outer circumferential edge and rotating the first chuck table to make at least one revolution about the rotational axis or preparing a laser processing unit capable of processing the first wafer with a laser beam, applying the laser beam from the laser processing unit to the outer circumferential edge of the first wafer, and rotating the first chuck table to make at least one revolution about the rotational axis.

Preferably, the method according to the aspect of the present invention further includes, after the outer circumferential edge of the first wafer has been processed, grinding the second surface side of the first wafer.

Preferably, the method according to the aspect of the present invention further includes, after the second surface side of the first wafer has been ground, depositing a thin film on the second surface side and the outer circumferential edge of the first wafer.

In accordance with another aspect of the present invention, there is provided a method of manufacturing a processed wafer by processing a first wafer having a beveled part on an outer circumferential edge thereof, including holding, on a first holding surface of a first chuck table, a second surface side of the first wafer that is opposite a first surface side thereof such that the first surface side of the first wafer is exposed and after the second surface side of the first wafer has been held, processing the outer circumferential edge of the first wafer to remove the beveled part on the outer circumferential edge in its entirety or a portion of the beveled part on the first surface side, in which the first wafer is progressively smaller in diameter from the first surface side toward the second surface side in a region of the outer circumferential edge of the first wafer that has been processed.

Preferably, in the method according to the other aspect of the present invention, the first chuck table is rotatable about a rotational axis extending through a center of the first holding surface across the first holding surface, and the outer circumferential edge of the first wafer is processed by either preparing a cutting blade mounted on a spindle along a direction parallel to the first holding surface and rotating the spindle to rotate the cutting blade while causing the cutting blade to cut into the outer circumferential edge of the first wafer and rotating the first chuck table to make at least one revolution about the rotational axis or preparing a laser processing unit capable of processing the first wafer with a laser beam and applying the laser beam from the laser processing unit to the outer circumferential edge of the first wafer while rotating the first chuck table to make at least one revolution about the rotational axis.

Preferably, the method according to the other aspect of the present invention further includes, after the outer circumferential edge of the first wafer has been processed, grinding the second surface side of the first wafer.

Preferably, the method according to the other aspect of the present invention further includes, after the second surface side of the first wafer has been ground, depositing a thin film on the second surface side and the outer circumferential edge of the first wafer.

In accordance with a further aspect of the present invention, there is provided a method of manufacturing a processed wafer by processing a first wafer having a beveled part on an outer circumferential edge thereof for use in a laminated wafer, including holding, on a first holding surface of a first chuck table, a second surface side of the first wafer that is opposite a first surface side thereof such that the first surface side of the first wafer is exposed, after the second surface side of the first wafer has been held, processing the outer circumferential edge of the first wafer to remove the beveled part on the outer circumferential edge in its entirety or a portion of the beveled part on the first surface side, after the outer circumferential edge of the first wafer has been processed, joining the first surface side of the first wafer to a second wafer to produce a laminated wafer, after the first surface side of the first wafer has been joined to the second wafer, holding, on a second holding surface of a second chuck table, the second wafer of the laminated wafer such that the second surface side of the first wafer is exposed, and after the second wafer of the laminated wafer has been held, processing the first wafer to manufacture the processed first wafer, in which the first wafer is progressively smaller in diameter from the first surface side toward the second surface side in a region of the outer circumferential edge of the first wafer that has been processed.

Preferably, in the method according to the further aspect of the present invention, the first wafer is processed by performing wet etching or chemical mechanical polishing on the first wafer.

Preferably, in the method according to the further aspect of the present invention, the first chuck table is rotatable about a rotational axis extending through a center of the first holding surface across the first holding surface, and the outer circumferential edge of the first wafer is processed by either preparing a cutting blade mounted on a spindle along a direction parallel to the first holding surface and rotating the spindle to rotate the cutting blade while causing the cutting blade to cut into the outer circumferential edge of the first wafer and rotating the first chuck table to make at least one revolution about the rotational axis or preparing a laser processing unit capable of processing the first wafer with a laser beam and applying the laser beam from the laser processing unit to the outer circumferential edge of the first wafer while rotating the first chuck table to make at least one revolution about the rotational axis.

In the method of processing a wafer and the method of manufacturing a processed wafer, first, the first chuck table holds the second surface side of the first wafer that is opposite the first surface such that the first surface side of the first wafer is exposed. Then, the outer circumferential edge of the first wafer is processed to remove the beveled part in its entirety or a portion of the beveled part. The first wafer is progressively smaller in diameter from the first surface side toward the second surface side in the region of the outer circumferential edge of the first wafer that has been processed. In this case, a wall surface that appears in the processed region of the outer circumferential edge of the first wafer does not extend steeply perpendicularly to the first surface. When wet etching is subsequently performed on the first wafer, therefore, the etching liquid flows smoothly down the wall surface and hence is not liable to remain on the first wafer. When the laminated wafer is produced and wet etching is performed on the laminated wafer, as the etching liquid flows smoothly from the laminated wafer, the joined area of the laminated wafer is less likely to suffer damage. When the first wafer is chemically and mechanically polished, since the polishing pad is elastically deformed and able to contact the wall surface, the wall surface is easily polished. Consequently, debris is less likely to occur from the outer circumferential edge of the first wafer.

Accordingly, the present invention provides a method of processing a wafer in a manner to prevent debris from occurring from an edge-trimmed outer circumferential edge of the wafer and a method of manufacturing a processed wafer in a manner to prevent debris from being produced from an edge-trimmed outer circumferential edge of the wafer.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a plan view schematically illustrating a first wafer;

FIG. 1B is a front elevational view schematically illustrating the first wafer;

FIG. 2 is a perspective view schematically illustrating a cutting apparatus as an example of a processing apparatus for performing edge trimming;

FIG. 3A is a cross-sectional view schematically illustrating a first holding step;

FIG. 3B is a plan view schematically illustrating a cutting unit that has been positionally adjusted for an outer circumferential edge processing step and a first chuck table;

FIG. 4A is a front elevational view schematically illustrating the cutting unit that has been positionally adjusted for the outer circumferential edge processing step and the first chuck table;

FIG. 4B is a front elevational view schematically illustrating the manner in which the first wafer is cut in the outer circumferential edge processing step according to a first aspect of a first modification;

FIG. 5 is a front elevational view schematically illustrating the manner in which an outer circumferential edge of the first wafer is processed by a laser beam;

FIGS. 6A and 6B are front elevational views schematically illustrating the first wafer that has been subjected to the outer circumferential edge processing step;

FIG. 7 is a front elevational view schematically illustrating the manner in which a first surface of the first wafer is joined to a surface of a second wafer, i.e., a support wafer;

FIG. 8A is a plan view schematically illustrating a laminated wafer;

FIG. 8B is a front elevational view schematically illustrating the laminated wafer;

FIGS. 9A and 9B are front elevational views schematically illustrating the manner in which a grinding step is carried out;

FIG. 10A is a front elevational view schematically illustrating the manner in which a second holding step is carried out;

FIG. 10B is a front elevational view schematically illustrating the manner in which wet etching is carried out in a first wafer processing step;

FIG. 11A is a front elevational view, partly in cross section, schematically illustrating the manner in which the second holding step is carried out;

FIG. 11B is a front elevational view, partly in cross section, schematically illustrating the manner in which the first wafer processing step is carried out;

FIG. 12 is a cross-sectional view, partly in elevation, schematically illustrating the manner in which a film depositing step is carried out;

FIG. 13 is a flowchart of a sequence of steps of a method of processing a wafer and a method of manufacturing a processed wafer;

FIG. 14A is a front elevational view schematically illustrating the manner in which the first wafer is cut in a first stage of the outer circumferential edge processing step according to a second modification;

FIG. 14B is a front elevational view schematically illustrating the first wafer that has been subjected to the first stage of the outer circumferential edge processing step according to the second modification;

FIG. 15A is a front elevational view schematically illustrating the manner in which the first wafer is cut in a second stage of the outer circumferential edge processing step according to the second modification;

FIG. 15B is a front elevational view schematically illustrating the first wafer that has been subjected to the second stage of the outer circumferential edge processing step according to the second modification;

FIG. 16A is a front elevational view schematically illustrating the manner in which the first wafer is cut in a first stage of the outer circumferential edge processing step according to a third modification;

FIG. 16B is a front elevational view schematically illustrating the manner in which the first wafer is cut in a second stage of the outer circumferential edge processing step according to the third modification;

FIG. 17A is a front elevational view schematically illustrating the manner in which the first wafer is cut by a first surface side of a cutting blade in the outer circumferential edge processing step according to a fourth modification;

FIG. 17B is a front elevational view schematically illustrating the manner in which the first wafer is cut by a second surface side of the cutting blade in the outer circumferential edge processing step according to the fourth modification;

FIG. 18A is a front elevational view schematically illustrating the cutting unit and the first chuck table; and

FIG. 18B is a front elevational view schematically illustrating the manner in which the first wafer is cut in the outer circumferential edge processing step according to a second aspect of the first modification.

### DETAILED DESCRIPTION OF THE PREFERRED EMBODIMENT

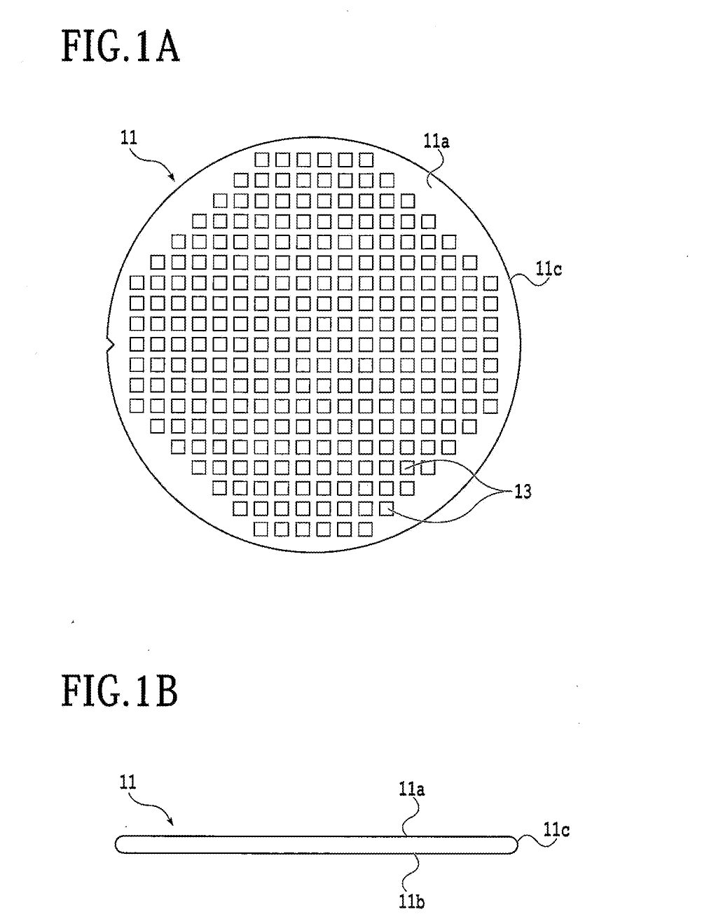

A preferred embodiment of the present invention will be described in detail below with reference to the accompanying drawings. FIG. 1A schematically illustrates a first wafer, also referred to as a “wafer,” 11 in plan, and FIG. 1B schematically illustrates the first wafer 11 in front elevation. The first wafer 11 illustrated in FIGS. 1A and 1B has a first surface 11a and a second surface 11b opposite the first surface 11a. The first surface 11a and the second surface 11b extend generally parallel to each other. The first wafer 11 is made of such a material as silicon (Si), silicon carbide (SiC), gallium nitride (GaN), gallium arsenide (GaAs), or some other semiconductor materials. However, though the first wafer 11 may preferably be made of the materials referred to above, it may not necessarily be made of them.

A plurality of devices 13 are fabricated in the first surface 11a side of the first wafer 11. The devices 13 may include, for example, semiconductor devices for use in ICs, semiconductor memories, or complementary metal oxide semiconductor (CMOS) image sensors. However, the devices 13 are not restricted to any types, numbers, shapes, structures, sizes, and layouts. The devices 13 are arranged in a matrix and are separated from each other by a grid of boundary lines. When the first wafer 11 is divided along the boundary lines, the first wafer 11 is fragmented into individual device chips, which may simply be referred to as chips. The boundary lines are called projected dicing lines or streets.

The first wafer 11 may also have recesses defined therein where interconnects such as through-silicon vias (TSVs) are disposed. The first wafer 11 has an outer circumferential edge 11c beveled. Stated otherwise, the first wafer 11 has a beveled part that is curved in a radially outwardly projecting shape on the outer circumferential edge 11c. In a method of processing a wafer and a method of manufacturing a processed wafer according to the present embodiment to be described below, the beveled part of the first wafer 11 or a portion of the beveled part on the first surface 11a side is removed by a process called edge trimming.

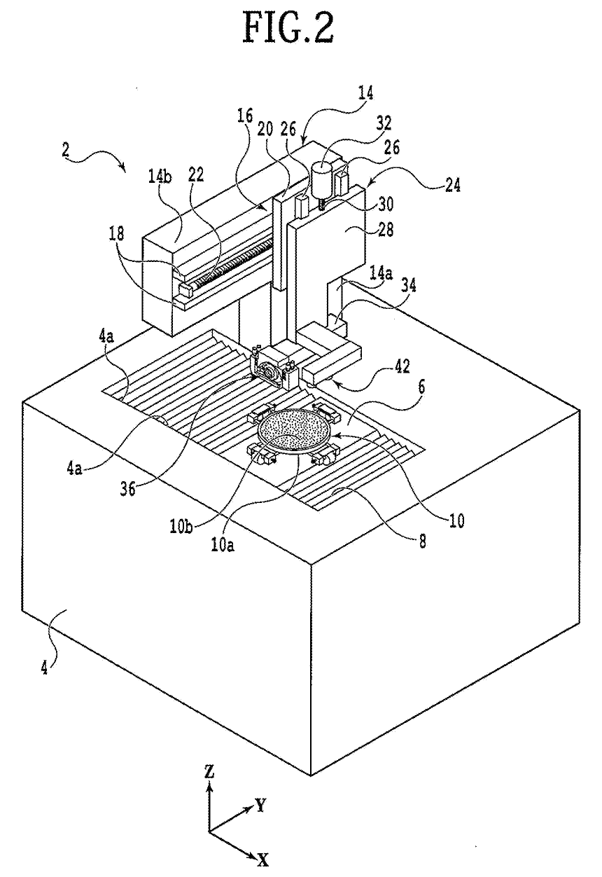

FIG. 2 schematically illustrates in perspective a cutting apparatus 2 as an example of a processing apparatus for performing edge trimming. In FIG. 2, a direction indicated by an arrow X, i.e., an X-direction, and a direction indicated by an arrow Y, i.e., a Y-direction, refer to horizontal directions that extend perpendicularly to each other in a horizontal plane. In addition, a direction indicated by an arrow Z, i.e., a Z-direction, refers to a vertical direction that extends perpendicularly to the X-direction and the Y-direction.

As illustrated in FIG. 2, the cutting apparatus 2 includes a base 4 supporting various components of the cutting apparatus 2 in and on itself. The base 4 has a cavity 4a defined therein that is open in its upper surface and that is of an elongate rectangular shape extending along the X-direction. The cavity 4a houses therein a table cover 6 shaped as a flat plate and a bellows-like dust-proof and drip-proof cover 8 that is expandable and contractible along the X-direction as the table cover 6 is moved along the X-direction.

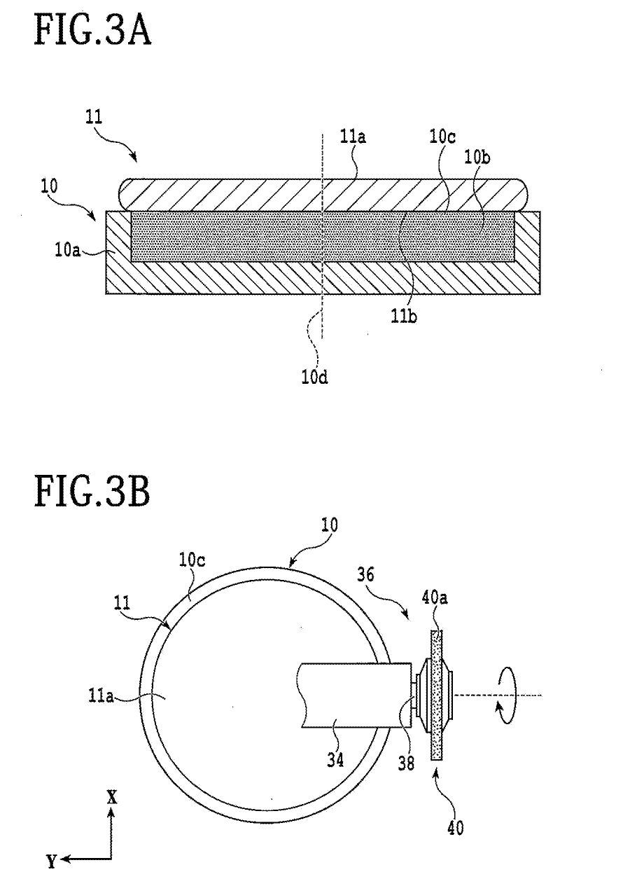

The table cover 6 supports thereon a first chuck table, also referred to as a “chuck table,” 10. FIG. 3A schematically illustrates the first chuck table 10 in cross section. The first chuck table 10 has a frame 10a shaped as a recessed circular plate made of ceramic, for example. The frame 10a includes a bottom wall shaped as a circular plate and a tubular side wall erected from an outer circumferential edge of the bottom wall. The bottom wall and the side wall jointly define an upwardly open recess in which there is fixedly disposed a circular porous plate 10b made of porous ceramic, for example. The porous plate 10b is substantially equal in diameter to a radially inner surface of the side wall of the frame 10a. The porous plate 10b is fluidly connected to an undepicted suction source such as an ejector, for example, placed in the cavity 4a in the base 4, through an undepicted fluid channel, for example, defined in the bottom wall of the frame 10a. The upper surface of the side wall of the frame 10a and the upper surface of the porous plate 10b lie flush with each other and extend parallel to the X-direction and the Y-direction. These upper surfaces jointly function as a first holding surface, also referred to as a “holding surface,” 10c of the first chuck table 10 for holding the first wafer 11.

When the first wafer 11 is introduced into the cutting apparatus 2, the first wafer 11 is placed on the first holding surface 10c of the first chuck table 10 such that the first surface 11a of the first wafer 11 faces upwardly. Then, the suction source fluidly connected to the porous plate 10b is actuated to create and apply a suction force to the porous plate 10b, holding under suction the second surface 11b side of the first wafer 11 on the first holding surface 10c with the first surface 11a side exposed upwardly.

The first chuck table 10 is coupled to an undepicted X-direction moving mechanism disposed in the cavity 4a in the base 4. The X-direction moving mechanism includes a ball screw operatively coupled to the first chuck table 10 and an electric motor for rotating a screw shaft of the ball screw about its longitudinal central axis. When the X-direction moving mechanism is actuated, it moves the first chuck table 10 along the X-direction or a direction opposite the X-direction. When the first chuck table 10 is thus moved, the table cover 6 is moved along the X-direction or the direction opposite the X-direction, and the dust-proof and drip-proof cover 8 is contracted and expanded. The first chuck table 10 is also coupled to an undepicted rotary actuator disposed in the cavity 4a. The rotary actuator includes a shaft coupled centrally to the first chuck table 10, a pulley operatively coupled to the shaft, and an electric motor for rotating the pulley about its central axis. When the rotary actuator is actuated, it rotates the first chuck table 10 about a rotational axis 10d extending through the center of the first holding surface 10c and across the first holding surface 10c. The rotational axis 10d extends perpendicularly to the first holding surface 10c, for example.

As illustrated in FIG. 2, the cutting apparatus 2 includes a support structure 14 mounted on the upper surface of the base 4 on one side of the cavity 4a closely to the cavity 4a. The support structure 14 includes an upright column 14a extending upwardly from the upper surface of the base 4 and an arm 14b extending from an upper portion of the upright column 14a in a direction opposite the Y-direction in overhanging relation to the cavity 4a. A Y-direction moving mechanism 16 is mounted on a front surface of the arm 14b that faces in the X-direction. The Y-direction moving mechanism 16 includes a pair of vertically spaced guide rails 18 that are fixedly attached to the front surface of the arm 14b and that extend along the Y-direction. A movable plate 20 is operatively mounted on front faces of the guide rails 18. The movable plate 20 is movable for sliding movement along the guide rails 18. The Y-direction moving mechanism 16 also includes a screw shaft 22 that is disposed between the guide rails 18 and that extends along the Y-direction. The screw shaft 22 has an end coupled to an undepicted electric motor for rotating the screw shaft 22 about its longitudinal central axis. The screw shaft 22 has an undepicted helical groove defined in its surface and is operatively threaded through an undepicted nut that houses a plurality of balls rollingly movable in the helical groove. The screw shaft 22, the electric motor, the nut, and the balls jointly make up a ball screw.

When the screw shaft 22 is rotated about its longitudinal central axis, the balls circulate through the nut while moving in the helical groove, causing the nut to move in the Y-direction or a direction opposite the Y-direction. The nut is fixed to a rear surface of the movable plate 20 that faces the arm 14b. Therefore, when the electric motor coupled to the end of the screw shaft 22 is energized to rotate the screw shaft 22, the movable plate 20 is moved in unison with the nut in the Y-direction or the direction opposite the Y-direction.

A Z-direction moving mechanism 24 is mounted on a front surface of the movable plate 20 that faces away from the arm 14b. The Z-direction moving mechanism 24 includes a pair of horizontally spaced guide rails 26 that are fixedly attached to the front surface of the movable plate 20 and that extend along the Z-direction. A movable plate 28 is operatively mounted on front faces of the guide rails 26. The movable plate 28 is movable for sliding movement along the guide rails 26. The Z-direction moving mechanism 24 also includes a screw shaft 30 that is disposed between the guide rails 26 and that extends along the Z-direction. The screw shaft 30 has an upper end coupled to an electric motor 32 for rotating the screw shaft 30 about its longitudinal central axis. The screw shaft 30 has an undepicted helical groove defined in its surface and is operatively threaded through an undepicted nut that houses a plurality of balls rollingly movable in the helical groove. The screw shaft 30, the electric motor 32, the nut, and the balls jointly make up a ball screw.

When the screw shaft 30 is rotated about its longitudinal central axis, the balls circulate through the nut while moving in the helical groove, causing the nut to move in the Z-direction or a direction opposite the Z-direction. The nut is fixed to a rear surface of the movable plate 28 that faces the arm 14b. Therefore, when the electric motor 32 coupled to the upper end of the screw shaft 30 is energized to rotate the screw shaft 30, the movable plate 28 is moved in unison with the nut in the Z-direction or the direction opposite the Z-direction.

A tubular housing 34 is fixed to a lower portion of the movable plate 28. The housing 34 houses therein part of a cutting unit 36. The cutting unit 36 has some components exposed out of the housing 34 over the first chuck table 10.

FIG. 3B schematically illustrates in plan the components of the cutting unit 36 that are exposed out of the housing 34 over the first chuck table 10. Specifically, the cutting unit 36 includes a spindle 38 extending generally along the Y-direction and having a distal end portion protruding from the housing 34. The spindle 38 is rotatably supported in the housing 34 for rotation about its longitudinal central axis along the Y-direction. The cutting unit 36 also includes a cutting blade 40 mounted on the protruding distal end portion of the spindle 38. The cutting blade 40 has an annular cutting edge 40a made of a binder of metal, ceramic, or resin, for example, and abrasive grains of diamond, for example, dispersed in the binder. The spindle 38 has a proximal end portion coupled to an undepicted rotary actuator such as an electric motor, for example, housed in the housing 34. When the rotary actuator is energized, it rotates the spindle 38 and hence the cutting blade 40 about their common central axis. When the cutting edge 40a of the rotating cutting blade 40 is brought into contact with the first wafer 11 on the first chuck table 10, the first wafer 11 is cut by the cutting blade 40.

Heretofore, when the cutting apparatus 2 performs edge trimming on the first wafer 11, it produces a wall surface extending near the outer circumferential edge 11c of the first wafer 11 perpendicularly to the first surface 11a thereof and a terrace extending from the base of the wall surface toward the outer circumferential edge 11c. The wall surface and the like suffer minute damage including cracks and chips caused by the edge trimming process. The damaged part may collapse into debris in subsequent processes on the first wafer 11. The debris is undesirable because it may scatter around onto the surfaces of the first wafer 11, tending to be detrimental to the quality of the device chips that will eventually be fabricated from the first wafer 11 by dividing the first wafer 11. According to one solution, the first wafer 11 that has been edge-trimmed is processed to remove the damaged area from the wall surface. The processes performed on the first wafer 11 to remove the damaged area may include an etching process using an etching solution, i.e., a wet etching process, and a polishing process using a soft polishing pad, e.g., a CMP process.

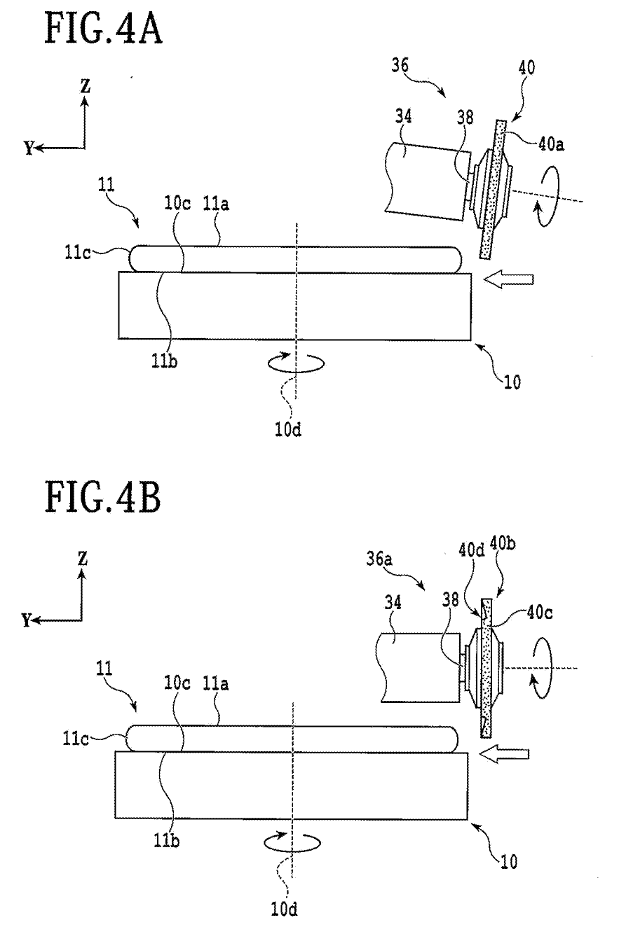

When the wet etching process is performed on the first wafer 11, the etching solution may be left on joints between the wall surface and the terrace, possibly causing yet other damage to the first wafer 11. In addition, when the first wafer 11 is polished by the CMP process, the polishing pad may fail to sufficiently polish the wall surface as the polishing pad is not likely to be brought into full contact the wall surface that lies perpendicularly to the first wafer 11. For this reason, it is preferable that the direction along which the spindle 38 extends be slightly tilted downwardly along the direction opposite the Z-direction toward the distal end thereof, instead of extending fully parallel to the Y-direction. FIG. 4A schematically illustrates in front elevation the spindle 38 that is slightly tilted from the Y-direction downwardly along the direction opposite the Z-direction. An edge trimming process carried out by the cutting unit 36 with the tilted spindle 38 and its advantages will be described in detail later. The tilted spindle 38 should have an angle of depression ranging from 0.1 to 30.0 degrees though the range may not necessarily be limitative. Alternatively, the spindle 38 may extend parallel to the Y-direction.

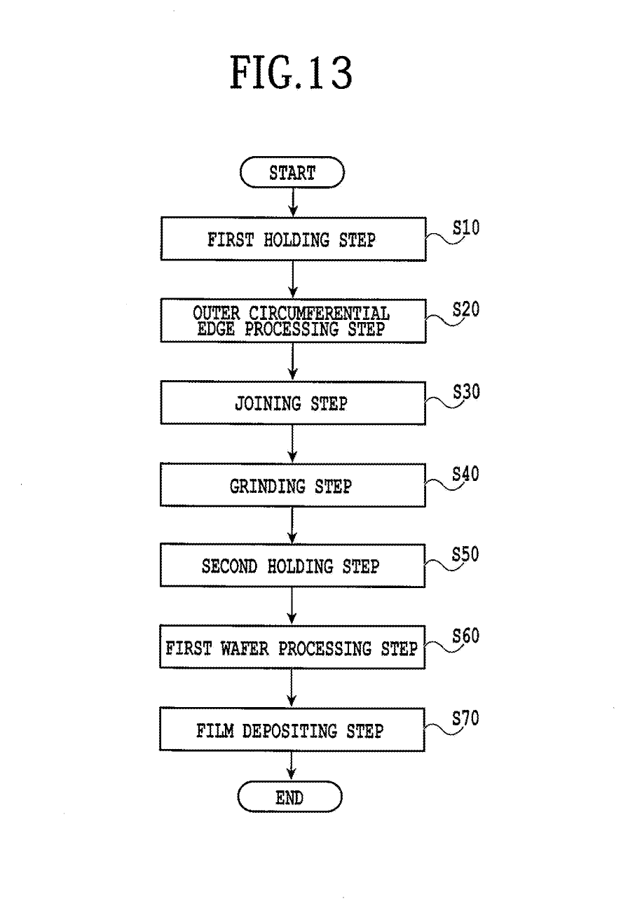

A method of processing a wafer by processing the first wafer 11 in a manner to prevent debris from being produced from an edge-trimmed outer circumferential edge 11c of the first wafer 11 according to the present embodiment and a method of manufacturing a processed wafer will be described below. FIG. 13 is a flowchart of a sequence of steps of the method of processing the wafer and the method of manufacturing the processed wafer. Not all the steps, illustrated in FIG. 13, of the method of processing the wafer and the method of manufacturing the processed wafer may be carried out, and some of the steps may be left out. The steps may not necessarily be carried out in the order illustrated in FIG. 13 unless otherwise mentioned, and may be switched around to the extent reasonable as the case may be.

In the method of processing the wafer by processing the first wafer 11 and the method of manufacturing the processed wafer, first holding step S10 is carried out at first. In first holding step S10, the first chuck table 10 holds on the first holding surface 10c the second surface 11b side of the first wafer 11 such that the first surface 11a side thereof that is opposite the second surface 11b side is exposed upwardly. FIG. 3A schematically illustrates in cross section the manner in which first holding step S10 is carried out. Specifically, in first holding step S10, the first wafer 11 is placed on the first holding surface 10c of the first chuck table 10 such that the first surface 11a of the first wafer 11 faces upwardly and has its center positioned on the rotational axis 10d of the first chuck table 10. Then, the suction source that is fluidly coupled to the porous plate 10b of the first chuck table 10 is actuated. The suction source creates and applies a suction force through the porous plate 10b to the first wafer 11. As a result, the first wafer 11 with its first surface 11a exposed upwardly is held under suction on the first holding surface 10c of the first chuck table 10.

First holding step S10 is followed by outer circumferential edge processing step S20 that processes the outer circumferential edge 11c of the first wafer 11 to remove the beveled part of the outer circumferential edge 11c in its entirety or a portion of the beveled part of the outer circumferential edge 11c on the first surface 11a side. Simply stated, edge trimming is performed on the first wafer 11 in outer circumferential edge processing step S20. Prior to edge trimming on the first wafer 11, the relative positional relation between the first chuck table 10 that is holding the first wafer 11 and the cutting unit 36 is adjusted. FIG. 3B schematically illustrates in plan the cutting unit 36 and the first chuck table 10 that have been adjusted in position for outer circumferential edge processing step S20. FIG. 4A schematically illustrates in front elevation the cutting unit 36 and the first chuck table 10 that have been adjusted in position for outer circumferential edge processing step S20. In FIG. 3B, the spindle 38 is not illustrated as tilted in the plan view.

The relative positions of the first chuck table 10 and the cutting unit 36 on an XY plane are determined such that the cutting blade 40 has a cutting tip, specifically, a lower end of the cutting edge 40a, positioned on a straight line along the Y-direction across the rotational axis 10d of the first chuck table 10. Stated otherwise, the relative positions of the first chuck table 10 and the cutting unit 36 on the XY plane are determined such that the lower end of the cutting edge 40a of the cutting blade 40 is positioned on a straight line extending along the direction opposite the Y-direction from a point on the beveled outer circumferential edge 11c of the first wafer 11 that is farthest from the center of the first wafer 11 along the direction opposite the Y-direction.

Moreover, the relative positions of the first chuck table 10 and the cutting unit 36 along the Z-direction are determined such that the lower end of the cutting edge 40a of the cutting blade 40 is positioned between the height of the first surface 11a of the first wafer 11 and the height of the second surface 11b thereof. With the first chuck table 10 and the cutting unit 36 thus positioned relatively to each other, a portion of the beveled part of the outer circumferential edge 11c of the first wafer 11 on the first surface 11a side is cut off and removed by the cutting edge 40a in outer circumferential edge processing step S20. Alternatively, the relative positions of the first chuck table 10 and the cutting unit 36 along the Z-direction are determined such that the lower end of the cutting edge 40a of the cutting blade 40 is positioned at the height of the second surface 11b of the first wafer 11. With the first chuck table 10 and the cutting unit 36 thus alternatively positioned relatively to each other, the entire beveled part of the outer circumferential edge 11c of the first wafer 11 is cut off and removed by the cutting edge 40a in outer circumferential edge processing step S20. Consequently, the relative positions of the first chuck table 10 and the cutting unit 36 along the Z-direction are determined in view of a region to be removed from the beveled part of the outer circumferential edge 11c of the first wafer 11.

The adjustment of the relative positions of the first chuck table 10 and the cutting unit 36 on the XY plane and the adjustment of the relative positions of the first chuck table 10 and the cutting unit 36 along the Z-direction may be performed in order to keep the cutting blade 40 out of contact with the first wafer 11, and may be carried out in any order or concurrent with each other.

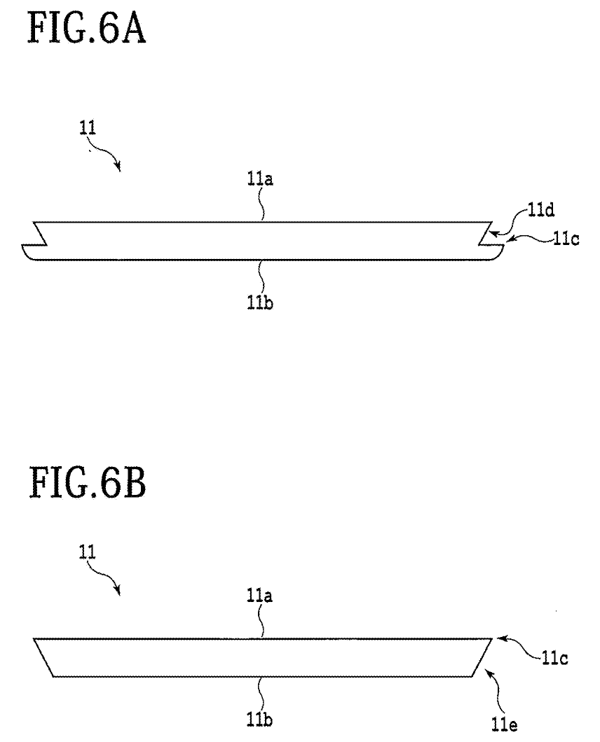

In outer circumferential edge processing step S20, the cutting blade 40 cuts the outer circumferential edge 11c of the first wafer 11 after the relative positions of the first chuck table 10 and the cutting unit 36 have been adjusted. FIG. 4A also schematically illustrates in front elevation the manner in which the cutting blade 40 cuts the beveled outer circumferential edge 11c of the first wafer 11 in outer circumferential edge processing step S20. FIGS. 6A and 6B schematically illustrate in front elevation the first wafer 11 that has been subjected to outer circumferential edge processing step S20.

For cutting the beveled outer circumferential edge 11c of the first wafer 11, the rotary actuator coupled to the spindle 38 is energized to start rotating the spindle 38 and rotate the cutting blade 40 at a speed of approximately 30,000 rpm. The rotary actuator coupled to the first chuck table 10 is actuated to start rotating the first chuck table 10 about the rotational axis 10d. Then, the cutting unit 36, i.e., the cutting edge 40a of the cutting blade 40, and the first chuck table 10 are relatively moved closer to each other along the Y-direction. The cutting edge 40a of the cutting blade 40 has its side surface side contacting the outer circumferential edge 11c of the first wafer 11, starting to cut the outer circumferential edge 11c. Stated otherwise, the beveled part of the outer circumferential edge 11c starts being cut off and removed, i.e., edge trimming starts to be performed on the beveled part of the outer circumferential edge 11c. When the cutting edge 40a has cut into the outer circumferential edge 11c radially inwardly over a predetermined distance, the cutting unit 36 and the first chuck table 10 stop being relatively moved along the Y-direction, thereby bringing the edge trimming process to an end.

If the lowermost end of the cutting edge 40a of the cutting blade 40 is positioned between the height of the first surface 11a of the first wafer 11 and the height of the second surface 11b thereof, then, as illustrated in FIG. 6A, a portion of the beveled part of the outer circumferential edge 11c on the first surface 11a side is removed, leaving a remainder of the beveled part of the outer circumferential edge 11c on the second surface 11b side unremoved. At this time, a slanted surface 11d appears on the outer circumferential edge 11c of the first wafer 11. Alternatively, if the lower end of the cutting edge 40a of the cutting blade 40 is positioned at the height of the second surface 11b of the first wafer 11, then, as illustrated in FIG. 6B, the beveled part of the outer circumferential edge 11c is removed in its entirety. At this time, a slanted surface 11e appears on the outer circumferential edge 11c of the first wafer 11. The angle of tilt of the slanted surface 11d or 11e, i.e., the angle formed between the first surface 11a and the slanted surface 11d or 11e, should preferably, but not necessarily, be in the range of 60.0 to 89.9 degrees.

Outer circumferential edge processing step S20 is not limited to the above sequence of step events. According to an alternative sequence of step events, for example, for cutting the outer circumferential edge 11c of the first wafer 11, the spindle 38 starts rotating, and then, the cutting unit 36, i.e., the cutting edge 40a of the cutting blade 40, and the first chuck table 10 are relatively moved closer to each other along the Y-direction, causing the cutting blade 40 to cut into the outer circumferential edge 11c. When the cutting edge 40a has cut into the outer circumferential edge 11c radially inwardly over a predetermined distance, the cutting unit 36 and the first chuck table 10 stop being relatively moved along the Y-direction. Then, the first chuck table 10 is rotated to make at least one revolution about the rotational axis 10d. The cutting unit 36 now performs edge trimming fully circumferentially on the outer circumferential edge 11c to form the slanted surface 11d or 11e on the outer circumferential edge 11c.

In the method of processing the wafer and the method of manufacturing the processed wafer, the direction along which the spindle 38 extends is tilted from the Y-direction downwardly along the direction opposite the Z-direction. Specifically, the direction along which the spindle 38 extends is tilted such that the distal end portion of the spindle 38 with the cutting blade 40 mounted thereon is lower than the proximal end portion of the spindle 38 that is housed in the housing 34. Therefore, a wall surface that appears at the removed region of the outer circumferential edge 11c does not extend steeply perpendicularly to the first surface 11a. In other words, the slanted surface 11d or 11e appears on the outer circumferential edge 11c.

Specifically, in the region of the outer circumferential edge 11c of the first wafer 11 that has been processed in outer circumferential edge processing step S20, the first wafer 11 becomes progressively smaller in diameter from the first surface 11a side toward the second surface 11b side. Stated otherwise, the slanted surface 11d or 11e is progressively slanted toward the center of the first wafer 11 in the direction from the first surface 11a side toward the second surface 11b side. In other words, the slanted surface 11d or 11e is inversely tapered downwardly. Upon wet etching to be performed subsequently on the first wafer 11, as described later, an etching liquid applied to the first wafer 11 tends to flow down the slanted surface 11d or 11e and is hence less liable to remain on the first wafer 11. If chemical mechanical polishing is performed on the first wafer 11, then the polishing pad is elastically deformed into contact with the slanted surface 11d or 11e, easily and effectively polishing the slanted surface 11d or 11e. Consequently, debris is less likely to occur from the outer circumferential edge 11c of the first wafer 11.

In first holding step S10, when the first wafer 11 is to be held under suction on the first chuck table 10, the vertical orientation of the first wafer 11 may be determined such that the first surface 11a side faces the first holding surface 10c and the second surface 11b side is exposed upwardly. In outer circumferential edge processing step S20, the first wafer 11 may be cut by the cutting unit 36 tilted such that the distal end portion of the spindle 38 with the cutting blade 40 mounted thereon is higher than the proximal end portion of the spindle 38 that is housed in the housing 34. Further, the cutting edge 40a of the cutting blade 40 may be brought closer to the first wafer 11 along the direction opposite the Z-direction from above the outer circumferential edge 11c, instead of being brought closer to the first wafer 11 along the Y-direction.

According to the above alternatives, when the first wafer 11 is held under suction on the first chuck table 10, the first surface 11a of the first wafer 11 is pressed against the first holding surface 10c, resulting in an undue burden on the first surface 11a. The devices 13 fabricated in the first surface 11a side of the first wafer 11 are also subjected to an undue burden. The devices 13 pressed against the first holding surface 10c may be damaged. Moreover, when the cutting edge 40a of the cutting blade 40 that moves along the direction opposite the Z-direction contacts the first wafer 11, a larger burden is applied to the devices 13.

In first holding step S10, by contrast, the vertical orientation of the first wafer 11 is determined such that the first surface 11a side faces upwardly. In outer circumferential edge processing step S20, the cutting edge 40a of the cutting blade 40 approaches the first wafer 11 along the Y-direction. Therefore, upon edge trimming, the devices 13 fabricated in the first wafer 11 undergo a smaller burden and are less liable to be damaged.

It has been described above that the outer circumferential edge 11c of the first wafer 11 is processed by way of cutting in outer circumferential edge processing step S20. Specifically, the cutting blade 40 mounted on the spindle 38 is prepared. Then, the spindle 38 is rotated to rotate the cutting blade 40, and while the cutting blade 40 is cutting into the outer circumferential edge 11c, the first chuck table 10 is rotated to make at least one revolution about the rotational axis 10d. However, outer circumferential edge processing step S20 is not limited to the details described above. In outer circumferential edge processing step S20, a laser processing apparatus for processing the first wafer 11 with a laser beam may be used instead of the cutting apparatus 2 including the cutting blade 40. In other words, in outer circumferential edge processing step S20, edge trimming may be performed on the first wafer 11 by a laser processing process instead of a cutting process.

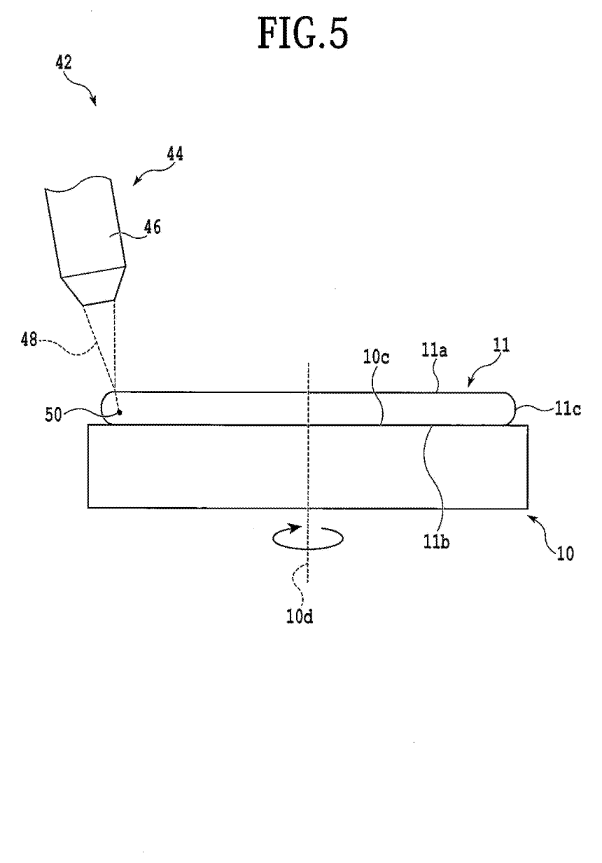

FIG. 5 schematically illustrates in front elevation the manner in which the outer circumferential edge 11c of the first wafer 11 is processed by a laser beam from a laser processing apparatus 42. As illustrated in FIG. 5, the laser processing apparatus 42 for performing a laser processing process on the first wafer 11 includes the first chuck table 10 that is identical to the first chuck table 10 of the cutting apparatus 2. Since the first chuck table 10 has been described in detail above, its detailed description will be omitted below.

The laser processing apparatus 42 includes a laser processing unit 44 for applying a laser beam to the first wafer 11 held under suction on the first chuck table 10, to process the first wafer 11 with the laser beam. The laser processing unit 44 includes an undepicted laser oscillator for emitting a laser beam, an undepicted optical system for adjusting the laser beam emitted from the laser oscillator and guiding the laser beam, and a processing head 46 for radiating a laser beam 48 from the optical system. The laser beam 48 radiated from the processing head 46 is focused into a focused spot. For processing the outer circumferential edge 11c of the first wafer 11 with the laser processing unit 44, the focused spot of the laser beam 48 is vertically positioned at the height of the first surface 11a of the first wafer 11, at the height of the second surface 11b of the first wafer 11, or between the height of the first surface 11a and the height of the second surface 11b. Alternatively, the focused spot of the laser beam 48 is vertically positioned at a height higher than the first surface 11a or a height lower than the second surface 11b in an area outside of the first wafer 11.

The laser beam 48 applied to the first wafer 11 has such a wavelength that the laser beam 48 can be absorbed by the first wafer 11, for example. When the laser beam 48 is applied to the first wafer 11, the laser beam 48 ablates the first wafer 11 at a point where the laser beam 48 is applied to the first wafer 11, removing a portion of the first wafer 11 and leaving a processed mark on the first wafer 11.

Alternatively, the laser beam 48 applied to the first wafer 11 has such a wavelength that the laser beam 48 can be transmitted in the first wafer 11. The laser beam 48 is applied to the first wafer 11 while its focused spot is being positioned within the first wafer 11 radially inwardly of the beveled outer circumferential edge 11c and near the beveled outer circumferential edge 11c. The laser beam 48 thus applied forms a modified region 50 within the first wafer 11 in the vicinity of the focused spot. FIG. 5 schematically illustrates the modified region 50 formed in the first wafer 11. The modified region 50 formed in the first wafer 11 functions as a division initiating point where the first wafer 11 is to start being divided. Specifically, at the time when the modified region 50 is formed in the first wafer 11, cracks are developed from the modified region 50, and the first wafer 11 will be divided from the modified region 50 and the cracks. Alternatively, after the modified region 50 has been formed in the first wafer 11, the cracks extend from the modified region 50 when the first wafer 11 is pressed, for example, and the first wafer 11 will be divided from the modified region 50 and the cracks.

At any rate, if outer circumferential edge processing step S20 is carried out by the laser processing apparatus 42, the laser processing unit 44 repeatedly applies the laser beam 48 to the outer circumferential edge 11c of the first wafer 11 held on the first chuck table 10, while the first chuck table 10 is being rotated about the rotational axis 10d. In this manner, the first wafer 11 is processed by the laser beam 48 fully circumferentially along the outer circumferential edge 11c, i.e., edge trimming is performed on the first wafer 11 by the laser processing process.

In the laser processing process, the laser beam 48 is applied to the first wafer 11 in a direction different from a direction perpendicular to the first surface 11a, i.e., a direction parallel to the Z-direction. More specifically, the processing head 46 orients the laser beam 48 such that the laser beam 48 as it travels from the processing head 46 toward the first wafer 11 becomes progressively closer to the center of the first wafer 11. When edge trimming is performed on the first wafer 11 with the laser beam 48 thus oriented while its focused spot is being positioned in the first wafer 11, the laser beam 48 forms an inversely tapered slanted surface 11d or 11e in the outer circumferential edge 11c of the first wafer 11. Specifically, when edge trimming is performed on the outer circumferential edge 11c of the first wafer 11 by the laser beam 48, in the region of the outer circumferential edge 11c of the first wafer 11 that has been processed in outer circumferential edge processing step S20, the first wafer 11 also becomes progressively smaller in diameter from the first surface 11a side toward the second surface 11b side.

The edge trimming process performed by the laser beam 48 is summarized as follows: In outer circumferential edge processing step S20, the laser processing unit 44 for processing the first wafer 11 with the laser beam 48 is prepared. Then, the first chuck table 10 is rotated to make at least one revolution about the rotational axis 10d while the laser processing unit 44 is applying the laser beam 48 to the outer circumferential edge 11c of the first wafer 11. In this manner, the first wafer 11 is edge-trimmed. Regardless of whether the first wafer 11 is cut by the cutting unit 36 or processed by the laser beam 48 in outer circumferential edge processing step S20, the first wafer 11 that has been processed is manufactured in outer circumferential edge processing step S20.

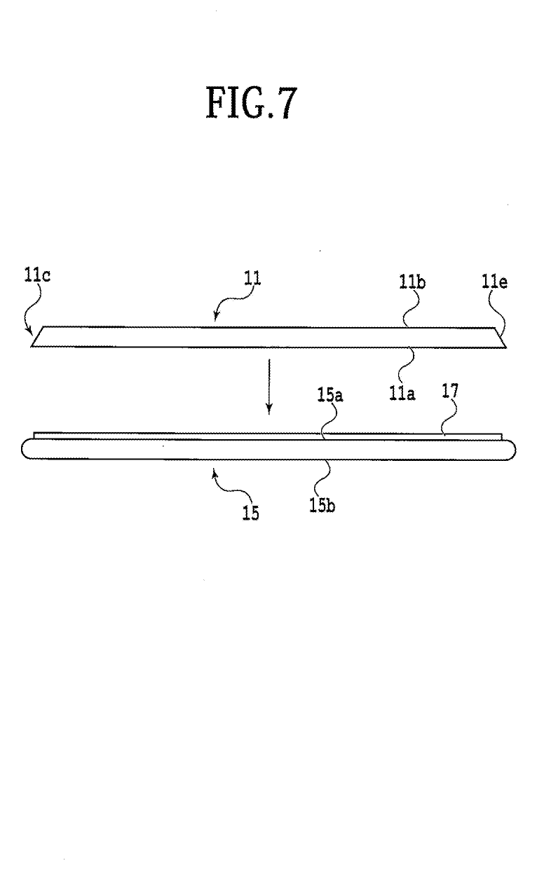

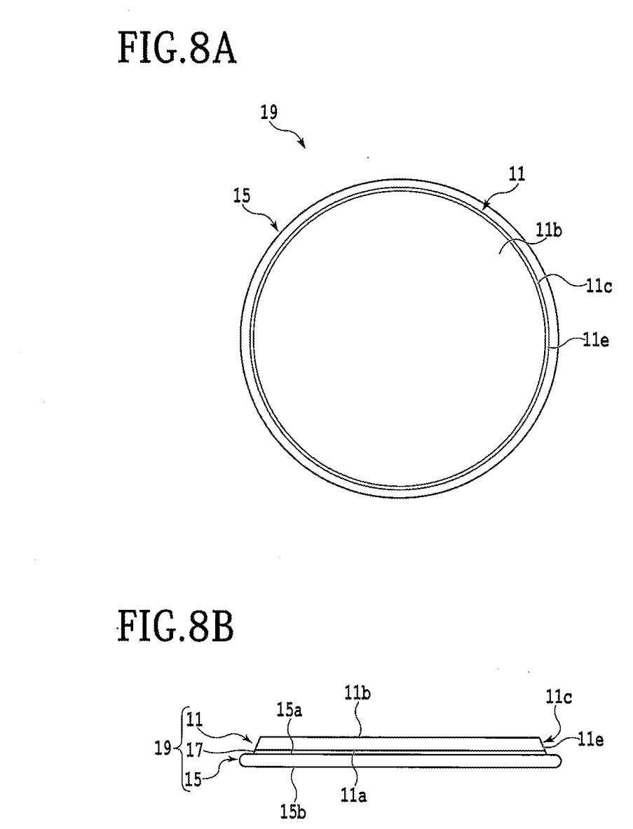

In the method of processing the wafer and the method of manufacturing the processed wafer, joining step S30 for joining the first surface 11a side of the first wafer 11 to a second wafer to produce a laminated wafer may be carried out after outer circumferential edge processing step S20. FIG. 7 schematically illustrates in front elevation the manner in which the first surface 11a side of the first wafer 11 is joined to one surface side of a second wafer, i.e., a support wafer, 15. FIG. 8A schematically illustrates in plan a laminated wafer 19 produced by joining the first wafer 11 and the second wafer 15 to each other. FIG. 8B schematically illustrates the laminated wafer 19 in front elevation. It is assumed hereinafter that the first wafer 11 that has the slanted surface 11e formed by removing the entire beveled part of the outer circumferential edge 11c from the first wafer 11 in outer circumferential edge processing step S20 as illustrated in FIG. 6B will be used in joining step S30. However, there may alternatively be used in joining step S30 the first wafer 11 having the slanted surface 11d formed by removing a portion of the beveled part of the outer circumferential edge 11c from the first wafer 11, leaving a remainder of the beveled part of the outer circumferential edge 11c on the second surface 11b side unremoved as illustrated in FIG. 6A.

The second wafer 15 illustrated in FIGS. 7 and 8B is identical in shape to the first wafer 11, for example. As with the first wafer 11, the second wafer 15 may have a plurality of devices in a first surface 15a side thereof. Alternatively, the second wafer 15 may have a plurality of devices in a second surface 15b side thereof. When the first wafer 11 and the second wafer 15 are joined to each other, the devices of the first wafer 11 and the devices of the second wafer 15 may be electrically connected to each other.

For joining the first wafer 11 and the second wafer 15 to each other in joining step S30, a joining layer 17 that contains an acryl-based adhesive or an epoxy-based adhesive is applied to the first surface 15a of the second wafer 15. The joining layer 17 is of a circular shape concentric to the second wafer 15 as viewed in plan and is smaller in radius than the second wafer 15. Then, while the second surface 15b side of the second wafer 15 is supported, the first surface 11a of the first wafer 11 is pressed against the first surface 15a of the second wafer 15 with the joining layer 17 interposed therebetween. The first wafer 11 and the second wafer 15 are now joined to each other by the joining layer 17, making up the laminated wafer 19. However, joining step S30 may not necessarily be limited to the above details, and the joining layer 17 may not be used in joining step S30.

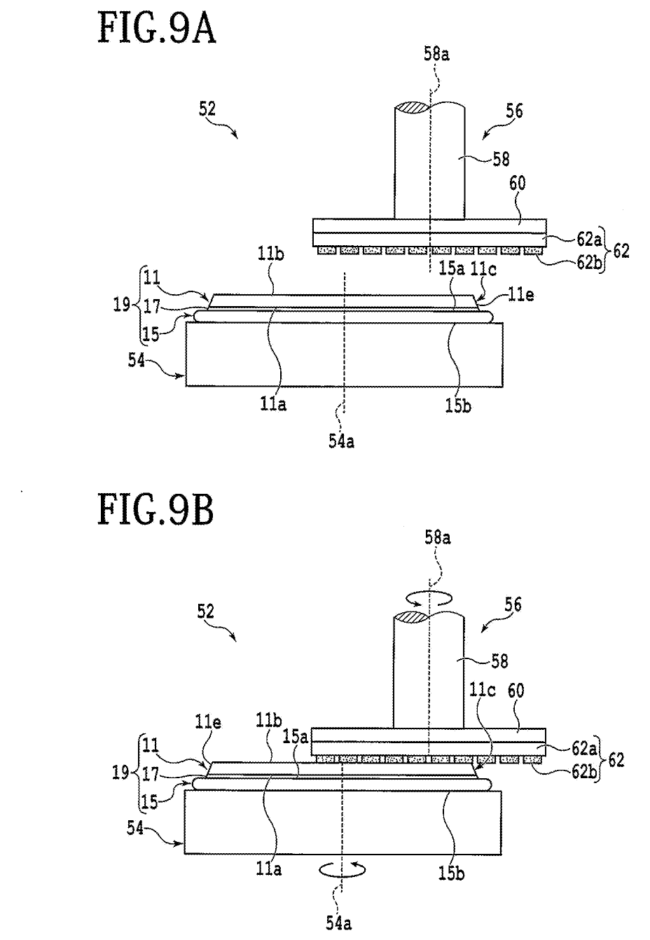

In the method of processing the wafer and the method of manufacturing the processed wafer, joining step S30 after outer circumferential edge processing step S20 may be followed by grinding step S40 for grinding the second surface 11b side of the first wafer 11 included in the laminated wafer 19. If joining step S30 is not carried out after outer circumferential edge processing step S20, then grinding step S40 for grinding the second surface 11b side of the first wafer 11 may be carried out after outer circumferential edge processing step S20. Each of FIGS. 9A and 9B schematically illustrates in front elevation the manner in which grinding step S40 is carried out by a grinding apparatus 52. In FIGS. 9A and 9B, the first wafer 11 that is part of the laminated wafer 19 is illustrated as being ground. However, the first wafer 11 that is not integrally joined to the second wafer 15 may be ground in grinding step S40.

The grinding apparatus 52 illustrated in FIGS. 9A and 9B includes a chuck table 54 that is similar in structure to the first chuck table 10 of the cutting apparatus 2 illustrated in FIG. 2. Specifically, the chuck table 54 has a circular holding surface where an undepicted porous plate is exposed upwardly. The holding surface of the chuck table 54 may not be of a circular shape, and may be shaped as the side surface of a cone.

The porous plate is fluidly connected to an undepicted suction source such as an ejector, for example, through an undepicted fluid channel, for example, defined in the chuck table 54. When the suction source is actuated, it creates and transmits a suction force through the fluid channel and the porous plate to a space near the holding surface of the chuck table 54. Therefore, when the suction source is actuated while the laminated wafer 19 or the first wafer 11 is being placed on the holding surface of the chuck table 54, the laminated wafer 19 or the first wafer 11 is held under suction on the holding surface of the chuck table 54. The chuck table 54 is coupled to an undepicted rotary actuator such as an electric motor, for example. When the rotary actuator is energized, it rotates the chuck table 54 about a rotational axis 54a extending through the center of the holding surface of the chuck table 54. The chuck table 54 may also be coupled to an undepicted horizontally moving mechanism for moving the chuck table 54 horizontally.

The grinding apparatus 52 includes a grinding unit 56 disposed above the chuck table 54 for grinding the second surface 11b side of the first wafer 11 on the chuck table 54. The grinding unit 56 has a spindle 58 extending vertically. The spindle 58 has an upper end coupled to an undepicted rotary actuator such as an electric motor, for example, and an undepicted vertically moving mechanism including a ball screw and an electric motor, for example. When the rotary actuator coupled to the spindle 58 is energized, it rotates the spindle 58 about a rotational axis 58a extending vertically. When the vertically moving mechanism is actuated, it moves the spindle 58 vertically. The spindle 58 has a lower end to which a disk-shaped mount 60 is fixed. The grinding unit 56 further includes a grinding wheel 62 mounted on the lower surface of the mount 60.

The grinding wheel 62 includes a disk-shaped wheel base 62a that is essentially equal in diameter to the mount 60 and an annular array of grindstones 62b fixed to a lower surface of the wheel base 62a, each of the grindstones 62b being of a cuboid shape. For example, each of the grindstones 62b is made of abrasive grains of diamond or cubic boron nitride (cBN) and a binder that binds the abrasive grains together. The binder may be a metal bond, a resin bond, or a vitrified bond, for example.

Disposed in the vicinity of the grinding wheel 62 is an undepicted grinding liquid supply nozzle for supplying an undepicted grinding liquid including water to the holding surface of the chuck table 54. Instead of or in addition to the grinding liquid supply nozzle, a fluid channel for supplying a grinding liquid therethrough to the holding surface of the chuck table 54 may be defined in the grinding wheel 62.

The grinding apparatus 52 carries out grinding step S40 according to the following sequence of step events, for example: First, the laminated wafer 19 or the first wafer 11 is placed on the chuck table 54 such that the second surface 11b of the first wafer 11 faces upwardly and has its center positioned on the rotational axis 54a of the chuck table 54. Then, the suction source that is fluidly coupled to the porous plate of the chuck table 54 is actuated. The suction source creates and applies a suction force through the porous plate to the laminated wafer 19 or the first wafer 11. As a result, the laminated wafer 19 or the first wafer 11 with the second surface 11b exposed upwardly is held under suction on the holding surface of the chuck table 54 (see FIG. 9A). Then, both the chuck table 54 and the spindle 58 are rotated, and the grinding liquid is supplied to the second surface 11b of the first wafer 11 through the grinding liquid supply nozzle and/or the fluid channel defined in the grinding wheel 62. While the chuck table 54 and the spindle 58 are being rotated and the grinding liquid is being supplied, the spindle 58 is lowered to bring the grindstones 62b into abrasive contact with the second surface 11b of the first wafer 11. In this manner, the second surface 11b side of the first wafer 11 is ground by the grindstones 62b (see FIG. 9B).

In grinding step S40, the second surface 11b of the first wafer 11 is ground to thin down the first wafer 11. Since the first wafer 11 has been edge-trimmed in outer circumferential edge processing step S20 prior to grinding step S40, a knife edge which would occur due to the beveled part upon thinning down the first wafer 11 is not present on the first wafer 11. Consequently, the first wafer 11 is free of damage caused by such a knife edge. If a portion of the beveled part of the outer circumferential edge 11c on the first surface 11a side of the first wafer 11 has been removed and a remainder of the beveled part of the outer circumferential edge 11c on the second surface 11b side has been left unremoved in outer circumferential edge processing step S20, then the remainder of the beveled part is removed in grinding step S40.

In the method of processing the wafer and the method of manufacturing the processed wafer, second holding step S50 and first wafer processing step S60 may be carried out after outer circumferential edge processing step S20. If joining step S30 is carried out, then second holding step S50 and first wafer processing step S60 may be carried out after joining step S30. If grinding step S40 is carried out, then second holding step S50 and first wafer processing step S60 may be carried out after grinding step S40. Now, second holding step S50 and first wafer processing step S60 that are carried out after joining step S30 and grinding step S40 will be described below.

A portion of the first wafer 11 in the vicinity of the outer circumferential edge 11c may be damaged as a result of the edge trimming process, i.e., the cutting process or the laser processing process, in outer circumferential edge processing step S20. Therefore, it is preferable to remove the portion of the first wafer 11 in the vicinity of the outer circumferential edge 11c after outer circumferential edge processing step S20, i.e., after the edge trimming process. In first wafer processing step S60, a process is carried out to remove the portion of the first wafer 11 in the vicinity of the outer circumferential edge 11c, for example. Specifically, wet etching or chemical mechanical polishing, for example, is performed on the first wafer 11 in first wafer processing step S60. In first wafer processing step S60, however, a process other than wet etching or chemical mechanical polishing may be carried out to remove the portion of the first wafer 11 in the vicinity of the outer circumferential edge 11c. Alternatively, a process other than the process for removing the portion of the first wafer 11 in the vicinity of the outer circumferential edge 11c may be carried out.

In second holding step S50 to be carried out prior to first wafer processing step S60, a second chuck table holds the first surface 11a side of the first wafer 11 on a second holding surface thereof such that the second surface 11b of the first wafer 11 is exposed upwardly. If joining step S30 is carried out, then the second chuck table holds the second wafer 15 side of the laminated wafer 19 in second holding step S50.

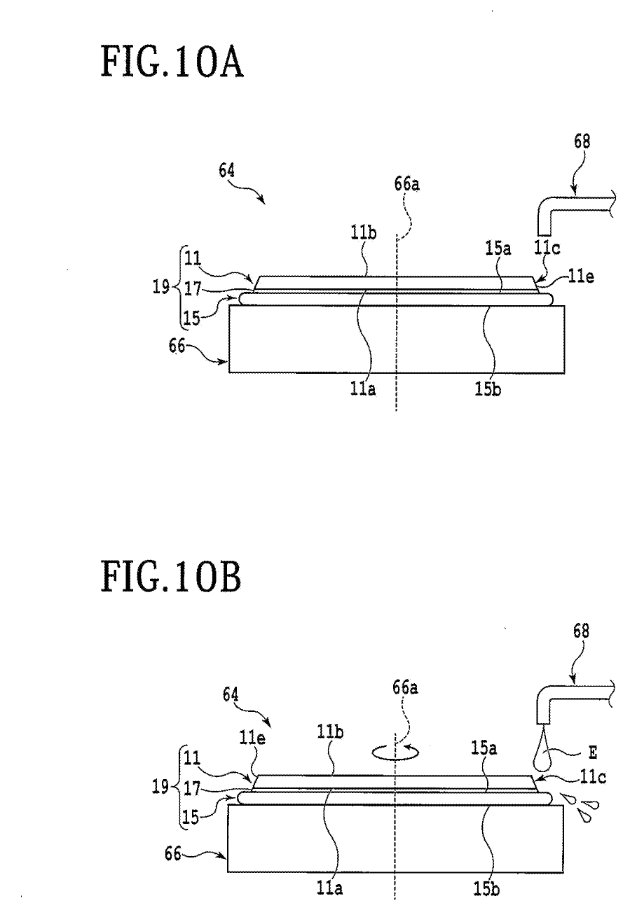

FIG. 10A schematically illustrates in front elevation the manner in which second holding step S50 is carried out by an etching apparatus 64. The etching apparatus 64 illustrated in FIG. 10A includes a second chuck table, also referred to as a “chuck table,” 66 that is similar in structure to the first chuck table 10 of the cutting apparatus 2 illustrated in FIG. 2. Specifically, the second chuck table 66 has a circular second holding surface, also referred to as a “holding surface,” where an undepicted porous plate is exposed upwardly.

The porous plate is fluidly connected to an undepicted suction source such as an ejector, for example, through an undepicted fluid channel, for example, defined in the second chuck table 66. When the suction source is actuated, it creates and transmits a suction force through the fluid channel and the porous plate to a space near the second holding surface of the second chuck table 66. Therefore, when the suction source is actuated while the laminated wafer 19 or the first wafer 11 is being placed on the second chuck table 66, the laminated wafer 19 or the first wafer 11 is held under suction on the second holding surface of the second chuck table 66. The second chuck table 66 is coupled to an undepicted rotary actuator such as an electric motor, for example. When the rotary actuator is energized, it rotates the second chuck table 66 about a rotational axis 66a extending through the center of the second holding surface of the second chuck table 66 perpendicularly thereto. The second chuck table 66 may also be coupled to an undepicted horizontally moving mechanism for moving the second chuck table 66 horizontally.

An etching liquid supply nozzle 68 is disposed above the second chuck table 66. The etching liquid supply nozzle 68 supplies an etching liquid E (see FIG. 10B) directly downwardly from a discharge port in its distal end. The etching liquid E contains a hydrofluoric acid, for example. The etching liquid supply nozzle 68 is movable horizontally. For example, the etching liquid supply nozzle 68 is horizontally swingable about its proximal end, which is not depicted.

The etching apparatus 64 carries out second holding step S50 and first wafer processing step S60 according to the following sequence of step events, for example: First, the laminated wafer 19 or the first wafer 11 is placed on the second chuck table 66 such that the second surface 11b of the first wafer 11 faces upwardly and has its center positioned on the rotational axis 66a of the second chuck table 66. Then, the suction source fluidly coupled to the porous plate of the second chuck table 66 is actuated to apply a suction force to the laminated wafer 19 or the first wafer 11. As a result, the laminated wafer 19 or the first wafer 11 is held under suction on the second holding surface of the second chuck table 66 with the second surface 11b of the first wafer 11 being exposed upwardly. Second holding step S50 is now finished.

After second holding step S50, wet etching is performed on the outer circumferential edge 11c side of the first wafer 11 in first wafer processing step S60. FIG. 10B schematically illustrates in front elevation the manner in which wet etching is performed on the outer circumferential edge 11c side of the first wafer 11 in first wafer processing step S60. In first wafer processing step S60, first, the second chuck table 66 and the etching liquid supply nozzle 68 are moved relatively to each other to position the outer circumferential edge 11c side of the first wafer 11 directly below the distal end of the etching liquid supply nozzle 68. Then, the second chuck table 66 is rotated about the rotational axis 66a while the etching liquid supply nozzle 68 is supplying the etching liquid E from the discharge port in the distal end thereof to the outer circumferential edge 11c side of the first wafer 11. The outer circumferential edge 11c side of the first wafer 11 is now etched by the etching liquid E to remove the portion of the first wafer 11 in the vicinity of the removed outer circumferential edge 11c that may have been damaged as a result of the edge trimming process in outer circumferential edge processing step S20.

In first wafer processing step S60, a region of the second surface 11b side of the first wafer 11 near its outer circumferential edge may be etched by the etching liquid E. Similarly, in first wafer processing step S60, a side surface side of the second wafer 15 may be etched by the etching liquid E. Moreover, in first wafer processing step S60, the entire second surface 11b side of the first wafer 11 may be etched by the etching liquid E. As described above, when edge trimming is performed on the beveled outer circumferential edge 11c of the first wafer 11 in outer circumferential edge processing step S20, the slanted surface 11d or 11e is formed on the outer circumferential edge 11c. Therefore, in first wafer processing step S60, the etching liquid E supplied to the outer circumferential edge 11c side flows smoothly down the slanted surface 11d or 11e and is not liable to stay around the first wafer 11.

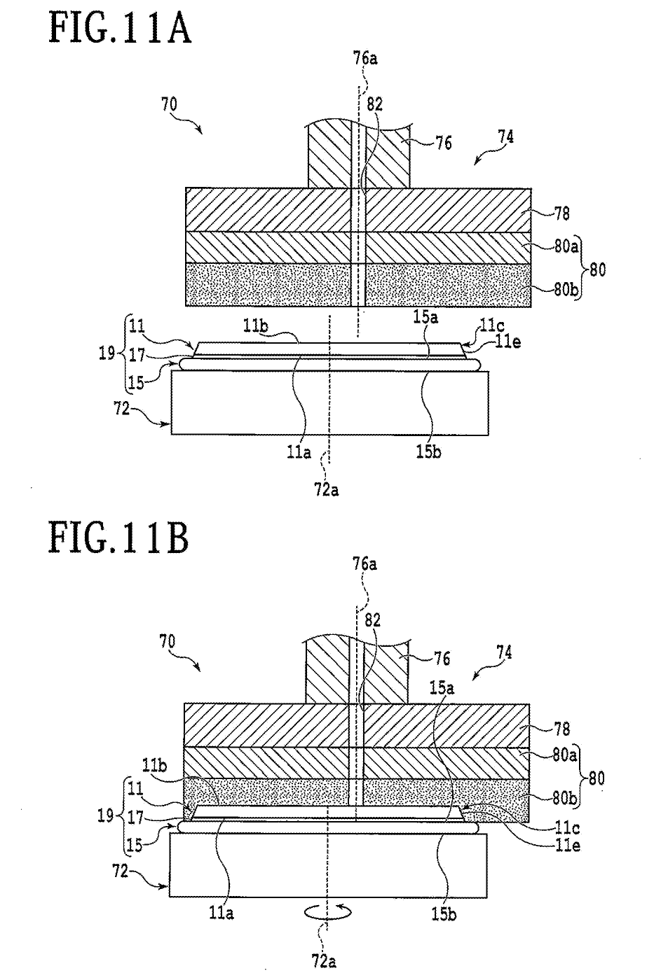

In first wafer processing step S60, chemical mechanical polishing may be carried out instead of or in addition to wet etching. If chemical mechanical polishing is carried out, then first wafer processing step S60 is performed by a polishing apparatus 70 illustrated in FIGS. 11A and 11B. In first wafer processing step S60, the laminated wafer 19 or the first wafer 11 is held on a second holding surface of a second chuck table, also referred to as a “chuck table,” of the polishing apparatus 70 such that the second surface 11b of the first wafer 11 is exposed upwardly. FIG. 11A schematically illustrates in front elevation, partly in cross section, the manner in which second holding step S50 is performed by the polishing apparatus 70. As illustrated in FIG. 11A, the polishing apparatus 70 includes a second chuck table 72 that is similar in structure to the first chuck table 10 of the cutting apparatus 2 illustrated in FIG. 2. Specifically, the second chuck table 72 has a circular second holding surface, also referred to as a “holding surface,” where an undepicted porous plate is exposed upwardly.

The porous plate is fluidly connected to an undepicted suction source such as an ejector, for example, through an undepicted fluid channel, for example, defined in the second chuck table 72. When the suction source is actuated, it creates and transmits a suction force through the fluid channel and the porous plate to a space near the second holding surface of the second chuck table 72. Therefore, when the suction source is actuated while the laminated wafer 19 or the first wafer 11 is being placed on the second chuck table 72, the laminated wafer 19 or the first wafer 11 is held under suction on the second holding surface of the second chuck table 72. The second chuck table 72 is coupled to an undepicted rotary actuator such as an electric motor, for example. When the rotary actuator is energized, it rotates the second chuck table 72 about a rotational axis 72a extending through the center of the second holding surface of the second chuck table 72 perpendicularly thereto. The second chuck table 72 may also be coupled to an undepicted horizontally moving mechanism for moving the second chuck table 72 horizontally.

A polishing unit 74 for chemically and mechanically polishing the second surface 11b side and the outer circumferential edge 11c side of the first wafer 11 is disposed over the second chuck table 72. The polishing unit 74 has a spindle 76 extending vertically. The spindle 76 has an upper end coupled to an undepicted rotary actuator such as an electric motor, for example, and an undepicted vertically moving mechanism including a ball screw and an electric motor, for example. When the rotary actuator coupled to the spindle 76 is energized, it rotates the spindle 76 about a rotational axis 76a extending vertically. When the vertically moving mechanism is actuated, it moves the spindle 76 vertically. The spindle 76 has a lower end to which a disk-shaped mount 78 is fixed. The polishing unit 74 further includes a disk-shaped polishing pad 80 mounted on the lower surface of the mount 78.

The polishing pad 80 includes a disk-shaped pad base 80a that is substantially equal in diameter to the mount 78 and a disk-shaped polishing layer 80b that is fixed to the lower surface of the pad base 80a and substantially equal in diameter to the mount 78. The polishing layer 80b is a fixed abrasive grain layer that contains abrasive grains dispersed therein. For example, the polishing layer 80b is fabricated by impregnating a piece of nonwoven fabric of polyester with an urethane solution in which abrasive grains having an average diameter ranging from 0.4 to 0.6 µm are dispersed and then drying the impregnated piece of nonwoven fabric. The abrasive grains dispersed in the polishing layer 80b are in the form of fine particles of SiC, cBN, diamond, or metal oxide, for example. The fine particles of metal oxide may be fine particles of silica (SiO₂), ceria (CeO₂), zirconia (ZrO₂), or alumina (Al₂O₃), for example.

The polishing layer 80b is pliable and elastically deformable under a pressure applied when the polishing unit 74 polishes the first wafer 11. For example, the polishing layer 80b is elastically deformable to allow the first wafer 11 to be embedded in the polishing layer 80b under a pressure applied when the polishing unit 74 polishes the second surface 11b side of the first wafer 11. In other words, the polishing layer 80b is elastically deformable in full contact with the entire outer circumferential edge 11c side of the first wafer 11. The polishing layer 80b thus elastically deformed polishes the second surface 11b of the first wafer 11 as well as the slanted surface 11d or 11e on the outer circumferential edge 11c side. The spindle 76, the mount 78, and the pad base 80a and the polishing layer 80b of the polishing pad 80 have respective diametrical centers essentially aligned with each other. A hollow cylindrical through hole 82 is defined axially through the spindle 76, the mount 78, and the pad base 80a, and the polishing layer 80b in alignment with these centers. In addition, the through hole 82 is fluidly connected to an undepicted slurry supply source that includes a slurry tank and a delivery pump, for example. When the delivery pump is actuated, it delivers an undepicted slurry containing various chemical components from the slurry tank via the through hole 82 to the second holding surface of the second chuck table 72. The slurry may or may not contain abrasive grains.

The polishing apparatus 70 carries out second holding step S50 in the following sequenced of step events, for example: First, the laminated wafer 19 or the first wafer 11 is placed on the second chuck table 72 such that the second surface 11b of the first wafer 11 faces upwardly and has its center positioned on the rotational axis 72a of the second chuck table 72. Then, the suction source that is fluidly coupled to the porous plate of the second chuck table 72 is actuated. The suction source creates and applies a suction force through the porous plate to the laminated wafer 19 or the first wafer 11. As a result, the laminated wafer 19 or the first wafer 11 with the second surface 11b exposed upwardly is held under suction on the second holding surface of the second chuck table 72. Second holding step S50 is now completed.

Second holding step S50 is followed by first processing step S60 in which the second surface 11b side and the outer circumferential edge 11c side of the first wafer 11 are chemically and mechanically polished. FIG. 11B schematically illustrates in front elevation, partly in cross section, the manner in which first wafer processing step S60 is carried out. In first wafer processing step S60, first, both the second chuck table 72 and the spindle 76 are rotated, and the slurry is supplied through the through hole 82 to the second surface 11b of the first wafer 11. While the second chuck table 72 and the spindle 76 are being rotated and the slurry is being supplied to the second surface 11b, the spindle 76 is lowered to cause the polishing layer 80b to press the first wafer 11 and to be elastically deformed until the first wafer 11 is embedded in the polishing layer 80b, i.e., until the polishing layer 80b is in full contact with the second surface 11b and the outer circumferential edge 11c in their entirety. In this fashion, the second surface 11b side and the outer circumferential edge 11c side of the first wafer 11 are chemically and mechanically polished by the polishing layer 80b, removing the portion of the first wafer 11 in the vicinity of the outer circumferential edge 11c that has been damaged as a result of the cutting of the outer circumferential edge 11c of the first wafer 11.

The slanted surface 11d or 11e is formed on the outer circumferential edge 11c of the first wafer 11 at the time when edge trimming is performed in outer circumferential edge processing step S20. Therefore, when the outer circumferential edge 11c is chemically and mechanically polished in first wafer processing step S60, the polishing layer 80b is brought into contact with the slanted surface 11d or 11e on the outer circumferential edge 11c without being excessively deformed. Accordingly, the outer circumferential edge 11c side of the first wafer 11 is easily polished by the polishing layer 80b. Regardless of whether wet etching or chemical mechanical polishing is performed on the first wafer 11 in first wafer processing step S60, the first wafer 11 that has been processed is obtained when first wafer processing step S60 is carried out.

As described above, the wall surface, i.e., the slanted surface 11d or 11e, that appears in the processed region of the outer circumferential edge 11c of the first wafer 11 in outer circumferential edge processing step S20 does not extend perpendicularly to the first surface 11a. Consequently, when wet etching is subsequently performed on the first wafer 11, the etching liquid E tends to flow down the wall surface and is hence less liable to remain on the first wafer 11. The first wafer 11 is thus less likely to suffer problems caused by the etching liquid E remaining thereon. If the first wafer 11 is chemically and mechanically polished, then since the elastically deformed polishing layer 80b is able to contact the wall surface easily, the wall surface is easily polished by the polishing layer 80b. As a consequence, debris is not likely to be produced from the outer circumferential edge 11c of the first wafer 11.

It has been described thus far that second holding step S50 and first wafer processing step S60 are carried out after grinding step S40. However, second holding step S50 and first wafer processing step S60 are not limited to the sequence described above. Rather, second holding step S50 and first wafer processing step S60 may be carried out before grinding step S40, for example.

In the method of processing the wafer and the method of manufacturing the processed wafer according to the present embodiment, film depositing step S70 for forming a thin film on the second surface 11b side and the outer circumferential edge 11c side of the first wafer 11 may be carried out after grinding step S40. If second holding step S50 and first wafer processing step S60 are carried out after polishing step S40, then film depositing step S70 may be carried out after second holding step S50 and first wafer processing step S60.

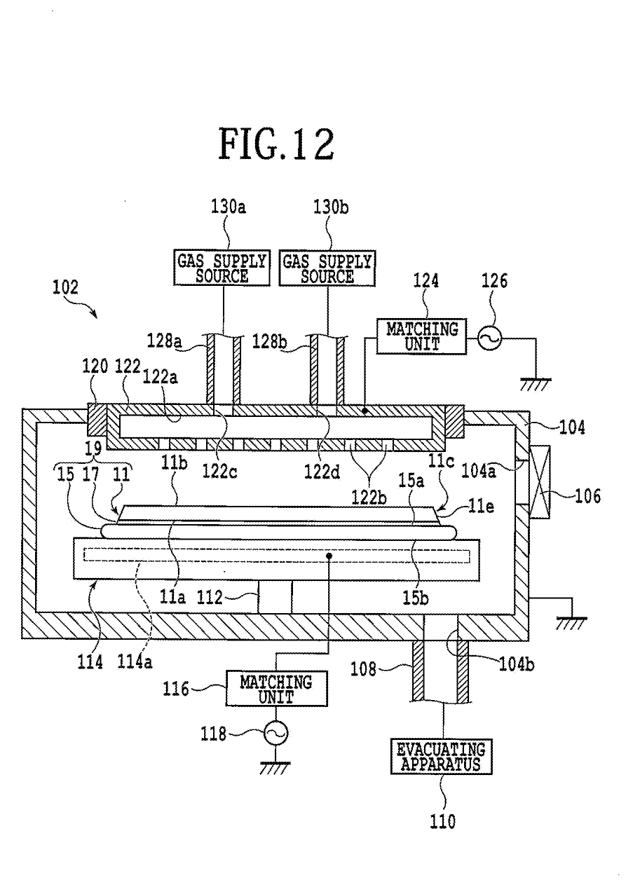

FIG. 12 schematically illustrates in cross-section, partly in elevation, the manner in which film depositing step S70 is carried out by a film depositing apparatus 102. As illustrated in FIG. 12, the film depositing apparatus 102 has a chamber 104 made of an electrically conductive material and connected to ground. The chamber 104 has an inlet/output port 104a that is defined in its side wall and that is for loading the laminated wafer 19 or the first wafer 11 into the chamber 104 and unloading the laminated wafer 19 or the first wafer 11 out of the chamber 104 therethrough. The inlet/output port 104a is openable and closable by a gate valve 106 that selectably opens and closes the internal space in the chamber 104 into and from the external space around the chamber 104. The chamber 104 also has an exhaust port 104b that is defined in a bottom plate thereof and that is for evacuating the internal space in the chamber 104 therethrough. The exhaust port 104b is fluidly connected to an evacuating apparatus 110 such as a vacuum pump, for example, through a pipe 108. The chamber 104 houses therein a support column 112 that is mounted on the bottom plate and that supports a table 114 thereon. An undepicted electrostatic chuck is disposed on the table 114. The table 114 houses therein an electrode 114a shaped as a circular plate disposed beneath the electrostatic chuck. The electrode 114a is electrically connected to a high-frequency power supply 118 through a matching unit 116.

The chamber 104 also has a circular opening defined in an upper plate thereof at a position facing the upper surface of the table 114. A gas ejection head 122 is rotatably supported by a bearing 120 in the circular opening in the chamber 104. The gas ejection head 122 is made of an electrically conductive material and electrically connected to a high-frequency power supply 126 through a matching unit 124. The gas ejection head 122 has a gas diffusion space 122a defined therein. The gas ejection head 122 also has a plurality of gas outlet ports 122b that are defined in an inner panel, e.g., a lower panel, thereof and that provide fluid communication between the gas diffusion space 122a and the internal space in the chamber 104. The gas ejection head 122 has two gas supply ports 122c and 122d that are defined in an outer panel, e.g., an upper panel, of the gas ejection head 122 and that are for supplying gases to the gas diffusion space 122a. The gas supply port 122c is fluidly connected through a pipe 128a to a gas supply source 130a for supplying a fluorocarbon gas such as C₄F₈ and/or a sulfur fluoride gas such as SF₆, for example. The gas supply port 122d is fluidly connected through a pipe 128b to a gas supply source 130b for supplying an inactive gas such as Ar and an O₂ gas, for example.

The film depositing apparatus 102 carries out film depositing step S70 according to the following sequence of step events, as follows: First, while the gate valve 106 is opening the internal space in the chamber 104 into the external space around the chamber 104, the laminated wafer 19 or the first wafer 11 is brought through the inlet/output port 104a into the chamber 104 and placed onto the table 114 such that the second surface 11b and the outer circumferential edge 11c of the first wafer 11 are exposed. Then, the electrostatic chuck on the table 114 is energized to hold the laminated wafer 19 or the first wafer 11 on the table 114. Thereafter, the evacuating apparatus 110 is actuated to evacuate the internal space in the chamber 104 to a vacuum. Then, anisotropic chemical vapor deposition (CVD) is carried out on the first wafer 11 in the chamber 104.

Specifically, the internal space in the chamber 104 is supplied with a gas containing C₄F₈ from the gas supply source 130a and a gas containing Ar from the gas supply source 130b. Then, the electrode 114a in the table 114 is supplied with high-frequency electric power from the high-frequency power supply 118, and the gas ejection head 122 is supplied with high-frequency electric power from the high-frequency power supply 126. Now, CF radicals are deposited on the second surface 11b and the outer circumferential edge 11c of the first wafer 11, forming a film containing fluorocarbon thereon. In film depositing step S70, anisotropic CVD is performed on the slanted surface 11d or 11e on the outer circumferential edge 11c. In this case, the film is deposited more easily on the outer circumferential edge 11c of the first wafer 11 than if a wall surface perpendicular to the first surface 11a is formed in place of the slanted surface 11d or 11e on the outer circumferential edge 11c and anisotropic CVD is performed on the perpendicular wall surface. In addition, the deposited film is less liable to be peeled off from the first wafer 11.

As described above, in the method of processing the wafer and the method of manufacturing the processed wafer according to the present embodiment, when the first wafer 11 is edge-trimmed, the slanted surface 11d or 11e, in place of a wall surface perpendicular to the first surface 11a, appears on the outer circumferential edge 11c. Therefore, debris is less likely to occur from a portion of the first wafer 11 in the vicinity of the outer circumferential edge 11c.

The present invention is not limited to the above description of the present embodiment, and various changes and modifications may be made in the embodiment. For example, according to the present embodiment, if outer circumferential edge processing step S20 is carried out by way of cutting, the first wafer 11 is cut by the cutting unit 36 of the cutting apparatus 2 with the spindle 38 tilted from the Y-direction. However, the present invention is not limited to such a feature. In outer circumferential edge processing step S20, the first wafer 11 is cut by the cutting unit 36 of the cutting apparatus 2 with the spindle 38 oriented to extend parallel to the Y-direction. According to such a modification, the cutting blade 40 should be changed in shape in order to form the slanted surface 11d or 11e on the outer circumferential edge 11c of the first wafer 11.

FIG. 4B schematically illustrates in front elevation the manner in which the first wafer 11 is cut in outer circumferential edge processing step S20 according to a first aspect of a first modification. In outer circumferential edge processing step S20 according to the first aspect of the first modification, there is used a cutting apparatus 2 including a cutting unit 36a with a modified cutting blade 40b mounted on the spindle 38.

The cutting blade 40b of the cutting unit 36a will be described below. FIG. 4B schematically illustrates a cutting edge 40c of the cutting blade 40b in cross section. As illustrated in FIG. 4B, the cutting edge 40c has a recess 40d defined in a side surface thereof. The recess 40d is defined in an annular area of the side surface that extends radially inwardly from the outer circumferential edge of the cutting edge 40c over a predetermined distance toward the center of the cutting blade 40b. The recess 40d is progressively deeper from the outer circumferential edge of the cutting edge 40c toward the center of the cutting blade 40b. Stated otherwise, the recess 40d has a slanted bottom surface that is progressively deeper along the direction away from the outer circumferential edge of the cutting edge 40c. The slanted bottom surface has an angle of tilt commensurate with the angle of tilt of the slanted surface 11d or 11c formed on the outer circumferential edge 11c of the first wafer 11 in outer circumferential edge processing step S20.

For performing outer circumferential edge processing step S20 using the cutting blade 40b, the orientation of the spindle 38 is directed parallel to the Y-direction. While the cutting blade 40b and the first chuck table 10 are being rotated, the cutting edge 40c is brought into contact with the outer circumferential edge 11c of the first wafer 11 along the Y-direction, cutting the first wafer 11. At this time, the cutting edge 40c forms a slanted surface 11d or 11e that is complementary in shape to the recess 40d in the cutting edge 40c on the outer circumferential edge 11c of the first wafer 11. When the cutting blade 40b with the recess 40d defined in the cutting edge 40c is thus used to cut the first wafer 11, it is not necessary to direct the orientation of the spindle 38 along a direction different from the Y-direction. Therefore, outer circumferential edge processing step S20 can be performed by a cutting apparatus 2 that is free of a mechanism for changing the orientation of the spindle 38 from the Y-direction, without the need for remodeling the cutting apparatus 2 itself.

In FIG. 4B, the recess 40d is defined in one of the two side surfaces of the cutting edge 40c that faces the housing 34. However, the recess 40d may be defined in a different position, and outer circumferential edge processing step S20 according to the first embodiment is not limited to the details illustrated in FIG. 4B.

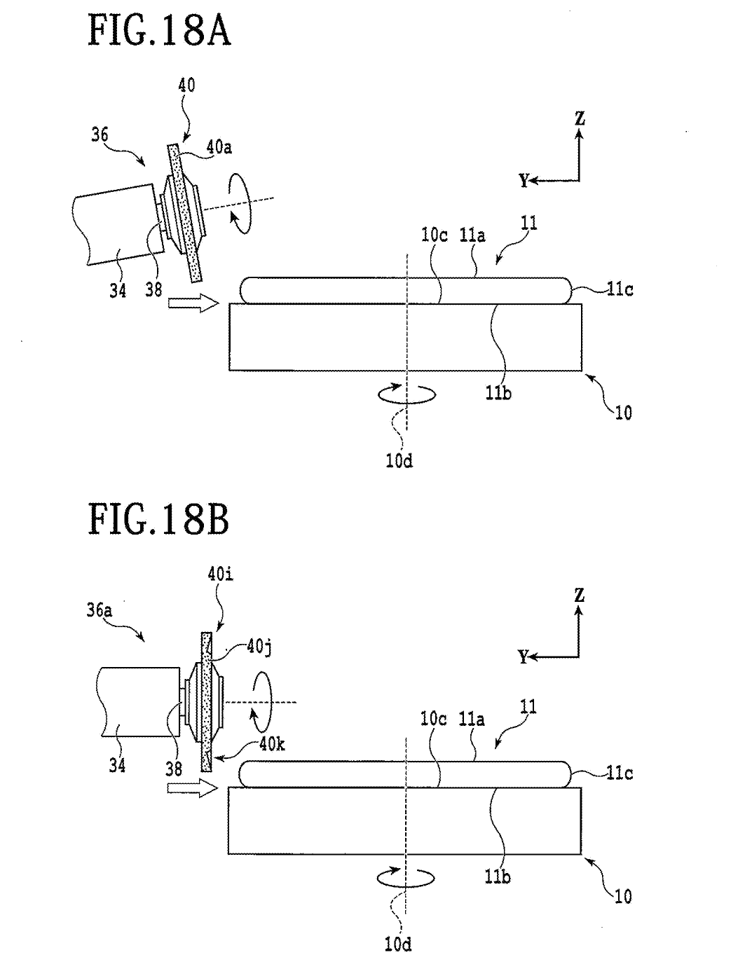

FIG. 18B schematically illustrates in front elevation the manner in which the first wafer 11 is cut in outer circumferential edge processing step S20 according to a second aspect of the first modification. In outer circumferential edge processing step S20 according to the second aspect of the first modification illustrated in FIG. 18B, as with outer circumferential edge processing step S20 according to the first aspect of the first modification, a cutting blade 40i having a recess 40k defined in a cutting edge 40j thereof is used. However, the recess 40k is defined in one of the two side surfaces of the cutting edge 40j that is different from the side surface of the cutting blade 40b where the recess 40d is defined as illustrated in FIG. 4B. Specifically, with the cutting blade 40i, the recess 40k is defined in the one of the two side surfaces of the cutting edge 40j that faces away from the housing 34. In outer circumferential edge processing step S20 according to the second aspect of the first modification, when the first wafer 11 is cut by the cutting blade 40i, the side surface side of the cutting blade 40i where the recess 40k is defined in the cutting edge 40j is brought into contact with the first wafer 11. The cutting blade 40i thus constructed and operated is able to form the slanted surface 11d (see FIG. 6A) in the first wafer 11 as with outer circumferential edge processing step S20 according to the first aspect of the first modification.

In outer circumferential edge processing step S20 described thus far, for cutting the first wafer 11, the cutting unit 36 or 36a is moved along the direction opposite the Y-direction. When the first wafer 11 is to be cut by the cutting unit 36 or 36a being moved along the direction, i.e., the direction in which the distal end of the spindle 38 is oriented, opposite the Y-direction, it is not necessary to use the cutting blade 40b or 40i where the recess 40d or 40k is defined in the cutting edge 40c or 40j. Rather, the first wafer 11 may be cut by the cutting blade 40 moving the cutting unit 36 along the direction opposite the Y-direction, the cutting blade 40 having the cutting edge 40a with no recess defined therein as illustrated in FIG. 4B.

FIG. 18A schematically illustrates in front elevation the cutting unit 36 and the first chuck table 10 at the time when the first wafer 11 is cut by the cutting blade 40 moving the cutting unit 36 along the direction opposite the Y-direction. As illustrated in FIG. 18A, the spindle 38 extends in a direction not fully parallel to the Y-direction but slightly tilted upwardly along the Z-direction toward the distal end of the spindle 38. In the case where the spindle 38 extends in the direction thus tilted, the angle of elevation of the spindle 38 should range from 0.1 to 30.0 degrees though the range may not necessarily be limitative. For cutting the first wafer 11, the position of the cutting blade 40 is determined such that the lower end of the cutting edge 40a of the cutting blade 40 is positioned on a straight line extending along the Y-direction from a point on the beveled outer circumferential edge 11c of the first wafer 11 that is farthest from the center of the first wafer 11 along the Y-direction.

For cutting the beveled outer circumferential edge 11c of the first wafer 11, the rotary actuator coupled to the spindle 38 is energized to start rotating the spindle 38 and rotate the cutting blade 40 at a speed of approximately 30,000 rpm. The rotary actuator coupled to the first chuck table 10 is actuated to start rotating the first chuck table 10 about the rotational axis 10d. Then, the cutting unit 36 and the first chuck table 10 are relatively moved closer to each other along the direction opposite the Y-direction. The cutting edge 40a of the cutting blade 40 has its side surface side contacting the outer circumferential edge 11c of the first wafer 11, starting to cut the outer circumferential edge 11c. Stated otherwise, the beveled part of the outer circumferential edge 11c starts being cut off and removed, i.e., edge trimming starts to be performed on the beveled part of the outer circumferential edge 11c. When the cutting edge 40a has cut into the outer circumferential edge 11c radially inwardly over a predetermined distance, the cutting unit 36 and the first chuck table 10 stop being relatively moved along the direction opposite the Y-direction, thereby bringing the edge trimming process to an end.

In this case, the cutting unit 36 is tilted such that the distal end portion of the spindle 38 with the cutting blade 40 mounted thereon is higher than the proximal end portion of the spindle 38 that is housed in the housing 34. Therefore, a wall surface that appears at the removed region of the outer circumferential edge 11c does not extend perpendicularly to the first surface 11a. In other words, the slanted surface 11d or 11e appears on the outer circumferential edge 11c. The angle of tilt of the slanted surface 11d or 11e, i.e., the angle formed between the first surface 11a and the slanted surface 11d or 11e, should preferably be in the range from 60.0 to 89.9 degrees. However, the angle of tilt of the slanted surface 11d or 11e may not be limited to this range.

For carrying out outer circumferential edge processing step S20 using the cutting blade 40b or 40i where the recess 40d or 40k is defined in the cutting edge 40c or 40j, a side surface of the cutting blade 40b or 40i where the recess 40d or 40k is not defined in the cutting edge 40c or 40j may be put to use. Outer circumferential edge processing step S20 according to a second modification will be described below. In outer circumferential edge processing step S20 according to the second modification, a first stage is initiated using the side surface of the cutting blade 40b or 40i where the recess 40d or 40k is not defined in the cutting edge 40c or 40j, followed by a second stage using the side surface of the cutting blade 40b or 40i where the recess 40d or 40k is defined in the cutting edge 40c or 40j.

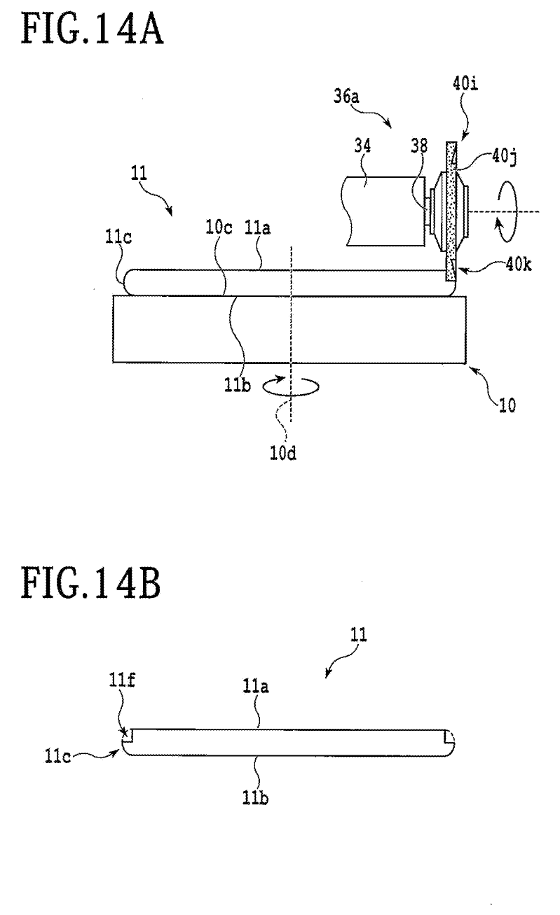

FIG. 14A schematically illustrates in front elevation the manner in which the first wafer 11 is cut in the first stage of outer circumferential edge processing step S20 according to the second modification. FIG. 14B schematically illustrates in front elevation the first wafer 11 that has been subjected to the first stage of outer circumferential edge processing step S20 according to the second modification. In FIG. 14A, the cutting edge 40j of the cutting blade 40i is illustrated in cross section for illustrative purposes. In the first stage of outer circumferential edge processing step S20 according to the second modification, while the cutting blade 40i and the first chuck table 10 are being rotated, the cutting edge 40j is brought into contact with the outer circumferential edge 11c of the first wafer 11 along the Y-direction, cutting the first wafer 11. Alternatively, the cutting edge 40j is brought downwardly into contact with the outer circumferential edge 11c of the first wafer 11, cutting the first wafer 11.

In the first stage of outer circumferential edge processing step S20 according to the second modification, the side surface of the cutting edge 40j where the recess 40k is not defined faces the rotational axis 10d of the first chuck table 10. Stated otherwise, the side surface of the cutting edge 40j where the recess 40k is not defined faces the center of the first wafer 11. In this case, the side surface of the cutting edge 40j where the recess 40k is defined does not contact the first wafer 11. If the side surface of the cutting edge 40j where the recess 40k is not defined extends along the Z-direction, then as illustrated in FIG. 14B, a temporarily trimmed area 11f that has a wall surface rising vertically along the Z-axis is formed in the outer circumferential edge 11c of the first wafer 11. At this time, the slanted surface 11d has not yet been formed in the outer circumferential edge 11c of the first wafer 11.

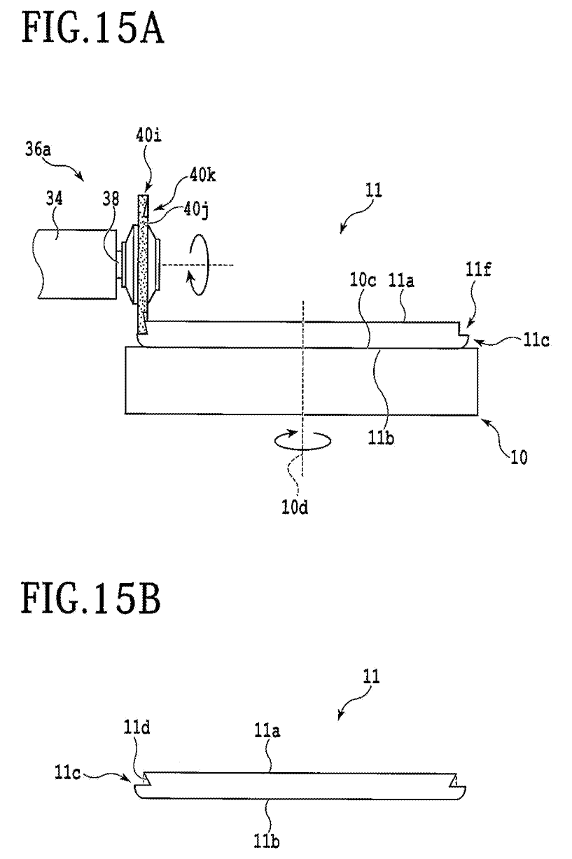

In the second stage of outer circumferential edge processing step S20 according to the second modification, while the cutting blade 40i and the first chuck table 10 are being rotated, the cutting edge 40j is brought into contact with the outer circumferential edge 11c of the first wafer 11 along the direction opposite the Y-direction, cutting the first wafer 11. FIG. 15A schematically illustrates in front elevation the manner in which the first wafer 11 is cut in the second stage of outer circumferential edge processing step S20 according to the second modification. FIG. 15B schematically illustrates in front elevation the first wafer 11 that has been subjected to the second stage of outer circumferential edge processing step S20 according to the second modification. In FIG. 15A, the cutting edge 40j of the cutting blade 40i is illustrated in cross section for illustrative purposes.

In the second stage of outer circumferential edge processing step S20 according to the second modification, the side surface of the cutting edge 40j where the recess 40k is defined faces the rotational axis 10d of the first chuck table 10. Stated otherwise, the side surface of the cutting edge 40j where the recess 40k is defined faces the center of the first wafer 11. In this case, the side surface of the cutting edge 40j where the recess 40k is defined contacts the first wafer 11. When the side surface of the cutting edge 40j where the recess 40k is defined contacts the first wafer 11, it forms the slanted surface 11d in the outer circumferential edge 11c of the first wafer 11, as illustrated in FIG. 15B.

As described above, outer circumferential edge processing step S20 according to the second modification is carried out in the first stage and then the second stage unlike outer circumferential edge processing step S20 according to the first modification. In the first and second stages, the different side surfaces of the cutting edge 40j of the cutting blade 40i are used respectively. If the outer circumferential edge 11c of the first wafer 11 is cut using only the side surface of the cutting blade 40i where the recess 40k is defined in the cutting edge 40j, the wear of the cutting edge 40j due to the cutting action is localized on the side surface of the cutting edge 40j. When the wear on the side surface of the cutting edge 40j exceeds an allowable limit, the cutting blade 40i needs to be replaced. On the other hand, when the different side surfaces of the cutting edge 40j of the cutting blade 40i are used respectively in the first and second stages, the wear of the cutting edge 40j is distributed to both of the side surfaces of the cutting edge 40j. As a result, the cutting blade 40i can be used to cut the first wafer 11 for a longer period of time until the wear on the side surface of the cutting edge 40j reaches the allowable limit. Therefore, the cutting blade 40i will be replaced less frequently.

The depth to which the first wafer 11 is to be ground off in the first stage of outer circumferential edge processing step S20 according to the second modification may be determined depending on the position and shape of the slanted surface 11d to be formed in the outer circumferential edge 11c of the first wafer 11. For example, in the first stage, the position of the cutting blade 40i along the Y-direction may be adjusted to prevent the cutting blade 40i from cutting the uppermost end, i.e., the end on the first surface 11a side, of an area where the slanted surface 11d is to be formed. Alternatively, the position of the cutting blade 40i along the Y-direction may be adjusted in order to cause both of the side surfaces of the cutting blade 40i to be worn more equally.

In outer circumferential edge processing step S20 according to the first and second modifications described thus far, only the cutting blade 40b or 40i where the recess 40d or 40k is defined in only one side surface of the cutting edge 40c or 40j is used. However, outer circumferential edge processing step S20 is not limited to such a detail. Rather, outer circumferential edge processing step S20 may use both the cutting blade 40 (see FIG. 4A) where no recess is defined in the cutting edge 40a and the cutting blade 40b or 40i where the recess 40d or 40k is defined in one side surface of the cutting edge 40c or 40j. Next, outer circumferential edge processing step S20 according to a third modification that uses both the cutting blade 40 and the cutting blade 40b will be described below. In outer circumferential edge processing step S20 according to the third modification, a first stage is initiated using the cutting blade 40 having the cutting edge 40a with no recess defined therein, followed by a second stage using the cutting blade 40i having the cutting edge 40j with the recess 40k defined therein.

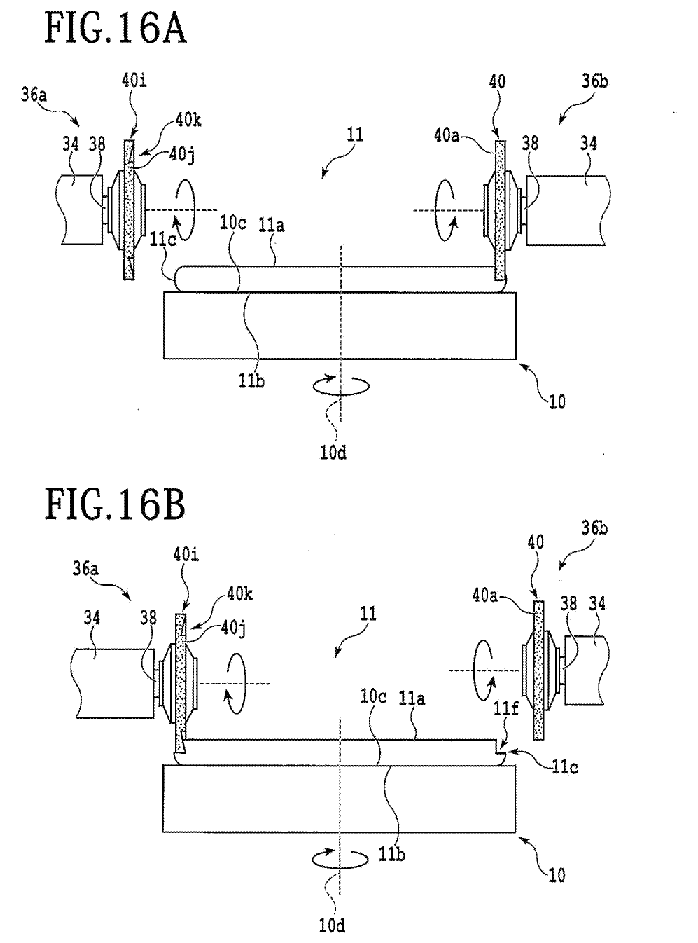

FIG. 16A schematically illustrates in front elevation the manner in which the first wafer 11 is cut in the first stage of outer circumferential edge processing step S20 according to the third modification. FIG. 16B schematically illustrates in front elevation the manner in which the first wafer 11 is cut in the second stage of outer circumferential edge processing step S20 according to the third modification. In FIGS. 16A and 16B, the cutting edges 40a and 40j of the cutting blades 40 and 40i are illustrated in cross section for illustrative purposes. A cutting apparatus for carrying out outer circumferential edge processing step S20 according to the third modification includes two cutting units 36a and 36b. The cutting unit 36b that is used in the first stage includes the cutting blade 40 having the cutting edge 40a with no recess defined therein. The cutting unit 36a that is used in the second stage includes the cutting blade 40i having the cutting edge 40j with the recess 40k defined therein.

In the first stage of outer circumferential edge processing step S20 according to the third modification, while the cutting blade 40 of the cutting unit 36b and the first chuck table 10 are being rotated, the cutting edge 40a is brought into contact with the outer circumferential edge 11c of the first wafer 11 along the Y-direction, cutting the first wafer 11. Alternatively, the cutting edge 40a is brought downwardly into contact with the outer circumferential edge 11c of the first wafer 11, cutting the first wafer 11. When the first wafer 11 is cut in the first stage, a temporarily trimmed area 11f is formed in the outer circumferential edge 11c of the first wafer 11. In the second stage of outer circumferential edge processing step S20 according to the third modification, while the cutting blade 40i of the cutting unit 36a and the first chuck table 10 are being rotated, the cutting edge 40j is brought into contact with the outer circumferential edge 11c of the first wafer 11 along the direction opposite the Y-direction, cutting the first wafer 11. At this time, because of the recess 40k in the cutting edge 40j, the cutting edge 40j forms the slanted surface 11d in the outer circumferential edge 11c of the first wafer 11.

In outer circumferential edge processing step S20 according to the third modification, the cutting blade 40 having the cutting edge 40a with no recess defined therein is used in the first stage, and the cutting blade 40i having the cutting edge 40j with the recess 40k defined therein is used in the second stage. The wear on the cutting blade 40i is smaller than if only the cutting edge 40j with the recess 40k defined therein is used in outer circumferential edge processing step S20.

Outer circumferential edge processing step S20 according to the third modification is not limited to the use of both the cutting blade 40 having the cutting edge 40a with no recess defined therein and the cutting blade 40i having the cutting edge 40j with the recess 40k defined therein. The two cutting units of the cutting apparatus used in outer circumferential edge processing step S20 according to the third modification may include the respective cutting blades 40b and 40i having the cutting edges 40c and 40j with the recesses 40d and 40k defined therein. In this case, for example, the first stage of outer circumferential edge processing step S20 is initiated by one of the cutting units, followed by the second stage of outer circumferential edge processing step S20 that is initiated by the other cutting unit.

Specifically, in the first stage, the side surface of the cutting blade 40b or 40i where the recess 40d or 40k is not defined in the cutting edge 40c or 40j of one of the cutting units contacts the first wafer 11. In the second stage, the side surface of the cutting blade 40b or 40i where the recess 40d or 40k is defined in the cutting edge 40c or 40j of the other one of the cutting units contacts the first wafer 11. Alternatively, in the first stage, the side surface of the cutting blade 40b or 40i where the recess 40d or 40k is not defined in the cutting edge 40c or 40j of the other one of the cutting units contacts the first wafer 11. In the second stage, the side surface of the cutting blade 40b or 40i where the recess 40d or 40k is defined in the cutting edge 40c or 40j of the one of the cutting units contacts the first wafer 11.

If outer circumferential edge processing step S20 is performed successively on a plurality of first wafers 11, then the two cutting blades 40b and 40i may alternately be used in each of the first stages, whereas the cutting blades 40b and 40i that are not used in the first stage may be used in the second stage. In outer circumferential edge processing step S20 according to the third modification, the two cutting blades 40b and 40i having the respective cutting edges 40c and 40j with the recesses 40d and 40k defined respectively therein can thus be used to make cutting blades 40b and 40i worn to the same degree. In other words, the two cutting blades 40b and 40i can be used to use up their service lives simultaneously. In this case, since the two cutting blades 40b and 40i can be replaced with fresh ones at the same time, the downtime of the cutting apparatus for cutting blade replacement is made shorter than if each of the two cutting blades 40b and 40i is replaced with its independent timing.

In outer circumferential edge processing step S20 according to the first modification, the second modification, and the third modification, the cutting blades 40b and 40i where the recesses 40d and 40k are defined in one of the side surfaces of the cutting edges 40c and 40j are used. However, a cutting blade with a recess defined therein that can be used in outer circumferential edge processing step S20 is not limited to those cutting blades. Instead, a cutting blade having a cutting edge with recesses defined respectively in its both side surfaces may be used in outer circumferential edge processing step S20. Next, outer circumferential edge processing step S20 according to a fourth modification will be described below. In outer circumferential edge processing step S20 according to the fourth modification, a cutting blade having a cutting edge with recesses defined respectively in its both side surfaces is used.

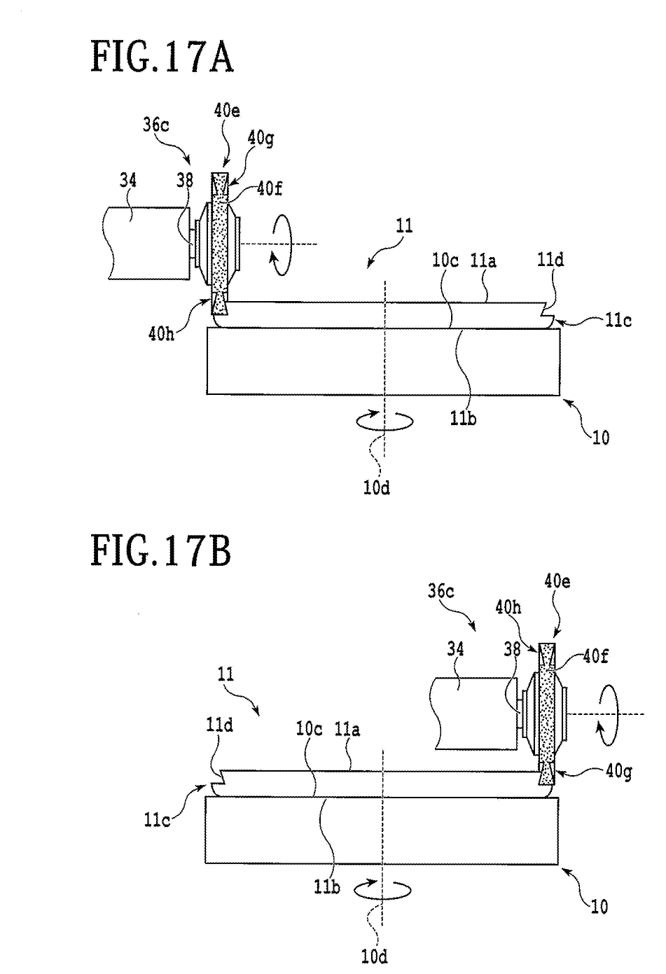

FIG. 17A schematically illustrates in front elevation the manner in which the first wafer 11 is cut by a first side surface side of a cutting blade 40e in outer circumferential edge processing step S20 according to the fourth modification. FIG. 17B schematically illustrates in front elevation the manner in which the first wafer 11 is cut by a second side surface side of the cutting blade 40e in outer circumferential edge processing step S20 according to the fourth modification. In FIGS. 17A and 17B, a cutting edge 40f of the cutting blade 40e is illustrated in cross section for illustrative purposes. Outer circumferential edge processing step S20 according to the fourth modification uses the cutting blade 40e having the cutting edge 40f that has a recess 40g defined in the first side surface side thereof and a recess 40h defined in the second side surface side thereof. A cutting apparatus that carries out outer circumferential edge processing step S20 according to the fourth modification includes a cutting unit 36c that has the cutting blade 40e.

In outer circumferential edge processing step S20 according to the fourth modification, while the cutting blade 40e and the first chuck table 10 are being rotated, the cutting edge 40f is brought into contact with the outer circumferential edge 11c of the first wafer 11 along the Y-direction or the opposite direction, cutting the first wafer 11. At this time, the cutting edge 40f forms a slanted surface 11d on the outer circumferential edge 11c of the first wafer 11. For cutting the first wafer 11, the first side surface side of the cutting edge 40f where the recess 40g is defined may be brought into contact with the first wafer 11, as illustrated in FIG. 17A. Alternatively, the second side surface side of the cutting edge 40f where the recess 40h is defined may be brought into contact with the first wafer 11, as illustrated in FIG. 17B.

If the cutting blade 40b having the cutting edge 40c where the recess 40d is defined in only one side surface thereof is used, for example, the side surface side is intensively worn. When the intensively worn side surface side is no longer usable, the cutting blade 40b reaches the end of its service life. On the other hand, when the cutting blade 40e having the cutting edge 40f with the recesses 40g and 40h defined in its both side surfaces is used to cut the first wafer 11, the cutting blade 40e can be used for a longer period of time. Specifically, even when the first side surface side of the cutting edge 40f where the recess 40g is defined can no longer be used due to wear, the second side surface side of the cutting edge 40f where the recess 40h is defined can be used to continue cutting the first wafer 11. When both the first side surface side and the second side surface side become unsuitable for cutting the first wafer 11, the end of the service life of the cutting blade 40e is reached. In other words, the cutting blade 40e having the cutting edge 40f with the recesses 40g and 40h defined in its both side surfaces can be used for a relatively long period of time.

With regard to the cutting blade 40e having the cutting edge 40f with the recesses 40g and 40h defined in its both side surfaces, the two recesses 40g and 40h do not need to be identical in shape to each other. The two recesses 40g and 40h may have different angles of tilt in a radial direction from the outer circumference to the center of the cutting edge 40f, for example. In this case, the single cutting blade 40e makes it possible to form either one of slanted surfaces 11d having two different angles of tilt selectively on the outer circumferential edge 11c of the first wafer 11.

For example, the recesses 40g and 40h are formed in the cutting edge 40f such that the angle of tilt of the slanted surface 11d of the recess 40g, which is referred to as a first angle of tilt, is a relatively large angle of tilt whereas the angle of tilt of the slanted surface 11d of the recess 40h, which is referred to as a second angle of tilt, is a relatively small angle of tilt. Then, if the slanted surface 11d whose angle of tilt is equal to the first angle of tilt is to be formed in the first wafer 11, the first side surface side of the cutting edge 40f where the recess 40g is defined is bought into contact with the first wafer 11, cutting the first wafer 11. On the other hand, if the slanted surface 11d whose angle of tilt is equal to the second angle of tilt is to be formed in the first wafer 11, the second side surface side of the cutting edge 40f where the recess 40h is defined is bought into contact with the first wafer 11, cutting the first wafer 11.

In the case where the angles of tilt of the two recesses 40g and 40h defined in the cutting edge 40f are thus different from each other, the single cutting blade 40e makes it possible to form either one of slanted surfaces 11d having two different angles of tilt selectively on the outer circumferential edge 11c of the first wafer 11. In this case, it is not necessary to replace the cutting blade included in the cutting apparatus when the angle of tilt of the slanted surface 11d to be formed in the first wafer 11 is changed.

According to the above embodiment, it has been described that grinding step S40 is carried out by the grinding apparatus 52 (see FIG. 9A) and that first wafer processing step S60 is carried out by the polishing step 70 (see FIG. 11A). However, the method of processing the wafer and the method of manufacturing the processed wafer are not limited to such features. Grinding step S40 and first wafer processing step S60 may be carried out by a grinding and polishing apparatus that includes the grinding unit 56 and the polishing unit 74, for example. The grinding and polishing apparatus may include a movable chuck table disposed below the grinding unit 56 and the polishing unit 74. The laminated wafer 19, i.e., the first wafer 11, held on the chuck table is ground by the grinding unit 56 and polished by the polishing unit 74. In other words, the laminated wafer 19, i.e., the first wafer 11, may be ground and chemically and mechanically polished while being held on the holding surface of the same chuck table. In this case, the chuck table 54 of the grinding apparatus 52 (see FIG. 9A) and the second chuck table 72 of the polishing apparatus 70 (see FIG. 11A) function as the same chuck table. This chuck table also functions as the second chuck table for holding the first wafer 11 in second holding step S50.

Moreover, according to the above embodiment, it has been described that, in first wafer processing step S60, the first wafer 11 is etched or chemically and mechanically polished and that grinding step S40 is carried out separately from first wafer processing step S60. However, the present embodiment is not limited to such details. According to the present invention, grinding step S40 may be carried out as first wafer processing step S60. In this case, in second holding step S50, the chuck table 54 of the grinding apparatus 52 functions as the second chuck table, and the first wafer 11 is ground in first wafer processing step S60.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a wafer by processing a first wafer having a beveled part on an outer circumferential edge thereof, comprising:
holding, on a first holding surface of a first chuck table, a second surface side of the first wafer that is opposite a first surface side thereof such that the first surface side of the first wafer is exposed; and
after the second surface side of the first wafer has been held, processing the outer circumferential edge of the first wafer to remove the beveled part on the outer circumferential edge of the first wafer in its entirety or a portion of the beveled part on the first surface side,
wherein the first wafer is progressively smaller in diameter from the first surface side toward the second surface side in a region of the outer circumferential edge of the first wafer that has been processed.

2. The method of processing a wafer according to claim 1,
wherein the first chuck table is rotatable about a rotational axis extending through a center of the first holding surface across the first holding surface, and
the outer circumferential edge of the first wafer is processed by either
preparing a cutting blade mounted on a spindle and rotating the spindle to rotate the cutting blade while causing the cutting blade to cut into the outer circumferential edge and rotating the first chuck table to make at least one revolution about the rotational axis, or
preparing a laser processing unit capable of processing the first wafer with a laser beam, applying the laser beam from the laser processing unit to the outer circumferential edge of the first wafer, and rotating the first chuck table to make at least one revolution about the rotational axis.

3. The method of processing a wafer according to claim 1, further comprising:
after the outer circumferential edge of the first wafer has been processed, grinding the second surface side of the first wafer.

4. The method of processing a wafer according to claim 3, further comprising:
after the second surface side of the first wafer has been ground, depositing a thin film on the second surface side and the outer circumferential edge of the first wafer.

5. A method of manufacturing a processed wafer by processing a first wafer having a beveled part on an outer circumferential edge thereof, comprising:
holding, on a first holding surface of a first chuck table, a second surface side of the first wafer that is opposite a first surface side thereof such that the first surface side of the first wafer is exposed; and
after the second surface side of the first wafer has been held, processing the outer circumferential edge of the first wafer to remove the beveled part on the outer circumferential edge in its entirety or a portion of the beveled part on the first surface side,
wherein the first wafer is progressively smaller in diameter from the first surface side toward the second surface side in a region of the outer circumferential edge of the first wafer that has been processed.

6. The method of manufacturing a processed wafer according to claim 5,
wherein the first chuck table is rotatable about a rotational axis extending through a center of the first holding surface across the first holding surface, and
the outer circumferential edge of the first wafer is processed by either
preparing a cutting blade mounted on a spindle along a direction parallel to the first holding surface and rotating the spindle to rotate the cutting blade while causing the cutting blade to cut into the outer circumferential edge of the first wafer and rotating the first chuck table to make at least one revolution about the rotational axis, or
preparing a laser processing unit capable of processing the first wafer with a laser beam and applying the laser beam from the laser processing unit to the outer circumferential edge of the first wafer while rotating the first chuck table to make at least one revolution about the rotational axis.

7. The method of manufacturing a processed wafer according to claim 5, further comprising:
after the outer circumferential edge of the first wafer has been processed, grinding the second surface side of the first wafer.

8. The method of manufacturing a processed wafer according to claim 7, further comprising:
after the second surface side of the first wafer has been ground, depositing a thin film on the second surface side and the outer circumferential edge of the first wafer.

9. A method of manufacturing a processed wafer by processing a first wafer having a beveled part on an outer circumferential edge thereof for use in a laminated wafer, comprising:
holding, on a first holding surface of a first chuck table, a second surface side of the first wafer that is opposite a first surface side thereof such that the first surface side of the first wafer is exposed;
after the second surface side of the first wafer has been held, processing the outer circumferential edge of the first wafer to remove the beveled part on the outer circumferential edge in its entirety or a portion of the beveled part on the first surface side;
after the outer circumferential edge of the first wafer has been processed, joining the first surface side of the first wafer to a second wafer to produce a laminated wafer;
after the first surface side of the first wafer has been joined to the second wafer, holding, on a second holding surface of a second chuck table, the second wafer of the laminated wafer such that the second surface side of the first wafer is exposed; and
after the second wafer of the laminated wafer has been held, processing the first wafer to manufacture the processed first wafer,
wherein the first wafer is progressively smaller in diameter from the first surface side toward the second surface side in a region of the outer circumferential edge of the first wafer that has been processed.

10. The method of manufacturing a processed wafer according to claim 9, wherein the first wafer is processed by performing wet etching or chemical mechanical polishing on the first wafer.

11. The method of manufacturing a processed wafer according to claim 9,
wherein the first chuck table is rotatable about a rotational axis extending through a center of the first holding surface across the first holding surface, and
the outer circumferential edge of the first wafer is processed by either
preparing a cutting blade mounted on a spindle along a direction parallel to the first holding surface and rotating the spindle to rotate the cutting blade while causing the cutting blade to cut into the outer circumferential edge of the first wafer and rotating the first chuck table to make at least one revolution about the rotational axis, or
preparing a laser processing unit capable of processing the first wafer with a laser beam and applying the laser beam from the laser processing unit to the outer circumferential edge of the first wafer while rotating the first chuck table to make at least one revolution about the rotational axis.
